(19) United States
(12) Patent Application Publication
(10) Pub. No.: US 2018/0261775 A1
(43) Pub. Date: Sep. 13, 2018

(54) ISOMERIC AND ASYMMETRIC MOLECULAR GLASS MIXTURES FOR OLED AND OTHER ORGANIC ELECTRONICS AND PHOTONICS APPLICATIONS

(71) Applicant: MOLECULAR GLASSES, INC., Rochester, NY (US)

(72) Inventor: Michel Frantz Molaire, Rochester, NY (US)

(21) Appl. No.: 15/761,244

(22) PCT Filed: Sep. 21, 2016
(86) PCT No.: PCT/US2016/052884

§ 371 Date: Mar. 19, 2018

Related U.S. Application Data
(60) Provisional application No. 62/221,605, filed on Sep. 21, 2015.

(51) Int. Cl. H01L 51/00; C09D 5/22; C09D 5/24; C09D 7/20; C09K 11/06; C09K 11/02

(52) U.S. Cl. CPC H01L 51/0067; C09D 5/22; C09D 5/24; H01L 51/5016; C09K 11/06; C09K 11/025; H01L 51/0072; C09D 7/20

(57) ABSTRACT

Embodiments of the present invention provide charge-transporting molecular glass mixtures, luminescent molecular glass mixtures, and combinations thereof with thermal properties that can be controlled independent of the structure of the core charge-transporting group, the luminescent group, or combination thereof. Each of the charge-transporting molecular glass mixture, the luminescent molecular glass mixture, and combinations thereof are defined as a mixture of compatible organic monomeric molecules with an infinitely low crystallization rate under the most favorable conditions. These can be formed in a one-part reaction of a mixture of a set of mono-functional materials having a common functionality with another set of mono-functional materials having a different common functionality; whereas the functionality of the first set is reactive to the functionality of the second set to yield an asymmetric condensation molecule. The “non-crystallizability” of the mixture is controlled by the asymmetric nature of and the number of the molecules of the mixture.

### CROSS REFERENCE TO RELATED APPLICATIONS

This application claims priority to U.S. Provisional Application No. 62/221,605, entitled ISOMERIC AND ASYMMETRIC MOLECULAR GLASS MIXTURES FOR OLED AND OTHER ORGANIC ELECTRONICS AND PHOTONICS APPLICATIONS, filed Sep. 21, 2015, the contents of which are incorporated by reference herein in their entirety.

### BACKGROUND OF THE INVENTION

Recently there has been increased interest into molecular glasses that can be coated into amorphous films for applications such as photoresist or molecular optoelectronic devices, including light-emitting diodes, field-effect transistors, and solar cells, as well as in advanced materials for xerography, two-photo absorption, luminescent devices, and photorefraction. One technique that is used in the art is a reverse of the principles of crystal engineering to devise molecules that resist crystallization. Examples of this technique are described in the publications by Eric Gagnon et al: “Triarylamines Designed to Form Molecular Glasses. Derivatives of Tris (p-terphenyl-4-yl) amine with multiple Contiguous Phenyl Substituents.” Organic Letters 201, Vol. 12, No. 3, p 404-407.

These molecular glasses produced via reverse crystallization engineering are defined as “amorphous materials in the state of thermodynamic non-equilibrium, and hence, they tend to undergo structural relaxation, exhibiting well-defined glass temperature (Tg's). However they also tend to crystallize on heating above their Tg's, frequently exhibiting polymorphism” (Hari Singh Nalwa, Advanced Functional Molecules and Polymers, Volume 3, CRC Press, 2001—Technology & Engineering; Yashuhiko Shirota and Hiroshi Kageyama, Chem. Rev. 2007, 107, 953-1010). With time, equilibrium will lead to crystallization of these non-equilibrium molecular glasses. Therefore crystallization is still a problem to be solved. When these non-equilibrium molecular glasses crystallize, the performance of a device comprising the non-equilibrium molecular glasses is degraded, limiting device longevity. An additional problem with current small molecule organic light emitting diode (OLED) materials is their solubility; either solubility is limited or requires non-green solvents. A further issue with molecular glass usage involves fluorescent emitters, particularly blue fluorescent emitters aggregation quenching. To suppress fluorescent quenching, blue fluorescent dyes have been doped in a host matrix. The blending system may intrinsically suffer from the limitation of efficiency and stability, aggregation of dopants and potential phase separation (M. Zhu and C Yang, Chem. Soc. Rev., 2013, 42, 4963). Another method used for blue fluorescent organic light emitting diodes (OLEDs) is nondoped blue fluorescent emitters. Still charge injection and transportation remain a problem.

Molaire in U.S. Pat. No. 4,499,165 disclosed nonpolymeric amorphous mixtures of compounds which are useful as a binder in optical recording layers. These mixtures were further used in nonpolymeric amorphous composition and developing processes (U.S. Pat. No. 5,176,977). Monomeric glass mixtures incorporating tetracarbonylbisimide groups were disclosed in U.S. Pat. No. 7,776,500. In U.S. Pat. No. 7,629,097 these mixtures found use in encapsulated toner compositions incorporating organic monomeric glasses. The entire disclosure of each of these United States patents is hereby incorporated by reference into this specification. In U.S. patent application Ser. Nos. 14/467,143 and 14/578,482 by Molaire, charge transporting molecular glass mixtures, bipolar charge-transporting molecular glass mixtures, electroluminescent (bipolar) molecular glass mixtures, and crosslinkable molecular glass mixtures are disclosed. In the molecular glass mixtures of those disclosures the mixture comprises at least two different components joining one multivalent organic nucleus with at least two organic nuclei wherein at least one of the multivalent organic nucleus and the organic nuclei is multicyclic, the linking group being an ester, urethane, amide or imide group.

Most luminescent organic molecules are pi-conjugated compounds, i.e., materials in which single and double or single and triple bonds alternate throughout the molecule or polymer backbone. For fine line photoresist applications it is important to minimize linking groups that contribute to light absorption above 250 nm. There is a need for non-crystallizable molecular glasses that are fully pi-conjugated. There is a need for non-crystallizable molecular glasses for resist applications.

There is a need for charge-transporting molecular glasses, luminescent molecular glasses, and combinations thereof that are truly non-crystallizable. There is further need for charge-transporting molecular glasses, luminescent molecular glasses, and combinations thereof with controllable thermal properties, independent of the structure of the charge transport moiety. There are specific needs for charge-transporting molecular glasses, luminescent molecular glasses, and combinations thereof that are relatively inexpensive to manufacture. There is a need to develop host matrix that will prevent phase separation of the guest emitter materials. There is also a need to develop luminescent emitters that will not aggregate in the first place. There is a need for charge-transporting molecular glasses, luminescent molecular glasses, and combinations thereof that are truly non-crystallizable. There is further need for charge-transporting molecular glasses, luminescent molecular glasses, and combinations thereof with large entropy of mixing to allow for complete compatibility of guest emitter materials. There is a further need for charge-transporting molecular glasses, luminescent molecular glasses, and combinations thereof where the polarity of transport can be easily modulated. There is still need for charge-transporting molecular glasses, luminescent molecular glasses, and the like that can be coated both by conventional thermal/vacuum process and solution printing process such as inkjet without modification, The present invention provides solutions for the above problems.

It is an object of this invention to provide asymmetric non-crystallizable molecular glasses. It is an object of this invention to provide isomeric and asymmetric non-crystallizable molecular glasses. It is an object of this invention to provide charge-transporting molecular glass mixtures, luminescent molecular glass mixtures, and combinations thereof with the many of the advantages illustrated herein. It is also an object of this invention to provide charge-transporting molecular glass mixtures, luminescent molecular glass mixtures, and combinations thereof that can be purified by simple and economic techniques. In another object of this invention there are provided charge-transporting molecular glass mixtures, luminescent molecular glass mixtures, and combinations thereof that can be easily dissolved in simple organic solvents. It is yet another object of this invention to provide charge-transporting molecular glass mixtures, luminescent molecular glass mixtures, and combinations thereof volatile and stable enough for vacuum deposition coatings. It is another object of this invention to provide charge-transporting molecular glass mixtures, luminescent molecular glass mixtures, and combinations thereof with uniform vapor pressure for vacuum deposition coatings without components fractionation. It is yet a further object of this invention to provide charge-transporting molecular glass mixtures, luminescent molecular glass mixtures, and combinations thereof with both sufficient electron-transporting and hole-transporting properties to support monolayer or simple device configuration.

### SUMMARY OF THE INVENTION

Various embodiments of the present invention provide for charge-transporting molecular glass mixtures, luminescent molecular glass mixtures, and combinations thereof with thermal properties that can be controlled independent of the structure of the core charge-transporting group, the luminescent group, or a combination thereof. The various embodiments used to describe the principles of the present invention are by way of illustration only and should not be construed in any way to limit the scope of the invention. Those skilled in the art will understand that the principles of the present invention may be implemented in any suitably arranged device.

The charge-transporting molecular glass mixtures, the luminescent molecular glass mixtures, and combinations thereof of this invention can be used particularly in light-emitting diodes, organic photovoltaic cells, field-effect transistors, organic light emitting transistors, organic light emitting chemical cells, electrophotography, and many other applications of the like.

Each of the charge-transporting molecular glass mixture, the luminescent molecular glass mixture, and combinations thereof of this invention are defined as a mixture of compatible organic monomeric molecules with an infinitely low crystallization rate under the most favorable conditions. These mixtures can be formed in a one-part reaction of a mixture of a set of mono-functional materials having a common functionality with another set of mono-functional materials having a different common functionality; whereas the functionality of the first set is reactive to the functionality of the second set to yield an asymmetric condensation molecule. The “non-crystallizability” of the mixture is controlled by the asymmetric nature of all the molecules of the mixture, and the number of molecules making up the mixture. Without being bound to theory, we predict that the asymmetric mixtures are more likely to be fully non-crystallizable.

Finally a glass mixture with partial component crystallization can be stabilized by mixing it with a non-crystallizable glass mixture in the right proportion. The mixed non-crystallizable glass mixture can be charge-transporting, luminescent, or even an inert non-crystallizable glass mixture.

The charge-transporting molecular glass mixtures, luminescent molecular glass mixtures, and combinations thereof like amorphous polymers, have good film-forming properties. However, unlike polymers, they display extremely low melt-viscosities, large positive entropy-of-mixing values, relatively high vapor pressure, and can be ground easily into extremely small particles. These properties make them ideal for certain applications where compatibility, defect-free film forming, melt-flow, vapor deposition coating, and small particle size are important. Charge-transporting molecular glass mixtures, luminescent molecular glass mixtures and combinations thereof of the invention when properly designed are truly non-crystallizable. Their thermal and other physical properties are tunable independent of the charge transport or luminescent moiety.

### BRIEF DESCRIPTION OF THE DRAWINGS

The invention will be described in more details by reference to the drawings, of which:

FIGS. 1A, 1B, 1C, 1D depict common OLED architectures with a hole-transporting material (HTM), and an electron-transport material (ETM) of the invention.

FIG. 2 is an HPLC chromatogram of Example 2 according to an embodiment of the invention.

FIG. 3 is an HPLC chromatogram of Example 2 according to an embodiment of the invention.

FIG. 4 is shows the glass transition temperature of Example 2 as measured by differential scanning calorimetry.

### DETAILED DESCRIPTION OF THE INVENTION

Various embodiments of the present invention provide for charge-transporting molecular glass mixtures, luminescent molecular glass mixtures, and combinations thereof. The various embodiments used to describe the principles of the present invention are by way of illustration only and should not be construed in any way to limit the scope of the invention. Those skilled in the art will understand that the principles of the present invention may be implemented in any suitably arranged device.

Definitions of Terms Used in this Application

Throughout this document, the following terms will have the following meanings.

The term “amorphous” means that the mixture is noncrystalline. That is, the mixture has no molecular lattice structure.

A “non-equilibrium molecular glass” is a glass forming material that is crystallizable under certain conditions, for example above the glass transition temperature, or in contact with certain solvents.

A “non-crystallizable molecular glass” will never crystallize under any circumstances and is always amorphous.

An “asymmetric glass mixture” is a glass mixture where all the components are asymmetric, i.e. have all distinct substituents.

A “isomeric glass mixture” is a glass mixture where all the components have the same molecular weight

“Green solvents” are non-toxic and benign to environment. A good guide of green solvents can be found in “Green chemistry tools to influence a medicinal chemistry and research chemistry based organization by K. Alfonsi, et al, Green Chem., 2008, 10, 31-36, DOI: 10.1039/b711717e. A list of “preferred”, “usable”, and undesirable solvents are shown in Table 1. The preferred solvents are considered “greener”. The undesirable solvents are to be avoided.

TABLE 1

| Preferred | Usable | Undesirable |
|---|---|---|
| Water | cyclohexane | pentane |
| acetone | methylcyclohexane | hexane |
| ethanol | toluene | di-isopropyl ether |
| 2-propanol | heptane | diethyl ether |
| 1-propanol | acetonitrile | dichloromethane |
| ethyl acetate | 2-methyltetrahydrofuran | dichloroethane |
| isopropyl acetate | tetrahydrofuran | dimethyl formamide |
| methanol | xylenes | N-methylpyrrolidone |
| 1-butanol | dimethylsulfoxide | pyridine |
| t-butanol | acetic acis | dimetyl acetamide |
| | ethylene glycol | diaxane |
| | | dimetoxyethane |
| | | benzene |
| | | carbon tetrachloride |

An “electronic device” is any device that uses electrons in its function, input or output.

The present invention provides charge-transporting molecular glass mixtures, luminescent molecular glass mixtures, and combinations thereof comprising at least two nonpolymeric compounds each independently corresponding to the structure of Formula (I), given as

′(R)—Y—(Z) (I)

wherein Y represents a triple bond, a double bond, or a single bond link; each R and Z represents independently a monovalent aliphatic or cycloaliphatic hydrocarbon group having 1 to 20 carbon atoms, an aromatic group or a multicyclic aromatic nucleus.

In one embodiment of the invention at least one of each R, or Z is independently a charge transporting moiety, a luminescent moiety, or a combination thereof; and

Y represents a triple bond, a double bond, or a single bond link.

In a second embodiment of the invention each R and Z is independently a monovalent hole-transporting moiety, a luminescent moiety, or a combination thereof; and

Y represents a triple bond, a double bond, or a single bond link.

In a third embodiment of the invention each R and Z is independently a monovalent electron-transporting moiety, a luminescent moiety, or a combination thereof; and

Y represents a triple bond, a double bond, or a single bond link.

In a fourth embodiment of the invention either R or Z is independently a monovalent electron-transporting moiety, a luminescent moiety, or a combination thereof; the other a monovalent hole-transporting moiety, a luminescent moiety, or a combination thereof; and

Y represents a triple bond, a double bond, or a single bond link.

In a fifth embodiment of the invention each R, or Z is independently a charge transporting moiety, a luminescent moiety, or a combination thereof; wherein each R independently has the same molecular weight, and each Z independently has the same molecular weight; and

Y represents a triple bond, a double bond, or a single bond link.

Charge-transporting molecular glass mixtures, luminescent molecular glass mixtures, and combinations thereof of the invention when properly designed are truly non-crystallizable. Their thermal and other physical properties are tunable independent of the charge transport or luminescent moiety.

The molecular glass mixtures of this invention are prepared according to various cross-coupling reactions known in the art, in particular cross-coupling reactions that have been proven suitable for producing conjugated polymers. An important object of this invention is to provide a method of providing amorphous, truly non-crystallizable molecular glass materials that can be easily purified by simple and economic processes. Truly amorphous materials by definition cannot be recrystallized. Thus because of that it is very difficult, or perhaps potentially costly to purify amorphous molecular glass materials containing high level of impurities and other compositions.

Accordingly, this invention only uses reactions that
1) are quantitative, that is the reaction is near 100% complete;
2) with either no byproducts; or
3) with byproducts that can be easily solubilized in water or other solvents, can be extracted efficiently, or can be easily solubilized in water or other solvents and extracted efficiently.

Cross-coupling reactions capable of producing polymers tend to be those that are quantitative. Specific examples of those cross-coupling reactions include the following reactions: the “Heck Reaction,” the “Suzuki Reaction,” the “Stille Coupling Reaction,” the “Sonogashira-Hagihara Coupling Reaction,” and the “Knoevenagel Reaction.”
The “Heck Reaction”, a palladium-catalyzed C—C coupling between aryl halides or vinyl halides and activated alkenes in the presence of a base (Heck R. F. J Am Chem Soc, 90:5518, 1968).

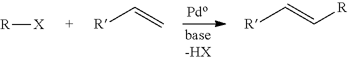

where R=alkenyl, aryl, allyl, alkynyl, benzyl;
X=halide, triflate; and
R′=alkyl, alkenyl, aryl, CO2R, OR, SiR3.
The “Suzuki Reaction”, the palladium (0) complex catalyzed reaction of an aryl- or vinyl-boronic acid with an aryl- or vinyl-halide in the presence of a base (Tanigaki N., Masuda H., and Kaeriyama K. Polymer, 38:1221, 1997; Remers M., Schulze M., and Wegner G. Macromol Rapid Commun, 17:239, 1996.)

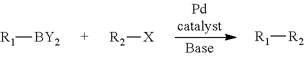

The halide or the boronate can be aryl or vinyl. R1=alkyl, alkenyl, alkynyl, aryl; Y=alkyl, OH, O-alkyl; R2=alkenyl, aryl, alkyl; x+, Cl, Br, I, OTf; Base=Sodium carbonate, Sodium hydroxide, M(O-alkyl), Potassium phosphate tribasic.
The “Stille Coupling Reaction”, a palladium-catalyzed coupling between an organostannane and halides or pseudohlaides to form C—C bond with few limitations on the R-groups. (Stille J. K. Angew Chem Int Ed, 25:508, 1986)

Organostannanes are not oxygen or moisture sensitive; however they are toxic and possess low polarity, ands are poorly soluble in water.
The “Sonogashira-Hagihara Coupling Reaction”, is the coupling of terminal alkynes with aromatic bromides or iodides performed in the presence of palladium catalyst a copper (I) co-catalyst and an amine base (Sonogashira K., Tohda Y., and Hagihara N. Tetrahedron Lett, 16:4467, 1975).

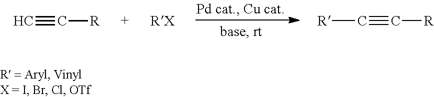

The “Knoevenagel Reaction” is a base-catalyzed condensation of a dialdehyde and an arene possessing two relatively acidic sites (benzylic protons) (Laue T. and Plagens A. Named Organic Reactions, 2nd Ed. John Wiley and Sons, 1999.; Horhold H. H. and Helbig M. Macromol Chem Macromol Symp, 12:229, 1987)

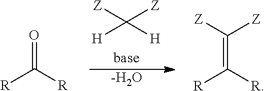

In this reaction the carbonyl group is an aldehyde or a ketone. The catalyst is usually a weakly basic amine. The active hydrogen component has the form
Z—CH₂—Z or Z—CHR—Z for instance diethyl malonate, Meldrum's acid, ethyl acetoacetate or malonic acid.
Z—CHR₁R₂ for instance nitromethane
   N-arylation of carbazoles and iminodiaryl coumpounds, such as the LiCL-mediated Catalytic Cul reaction reported in Bull. Korean Chem. Soc. 2011, Vol. 32, No. 7 2461, hereby incorporated by reference into this specification. A scheme of this reaction is shown below:

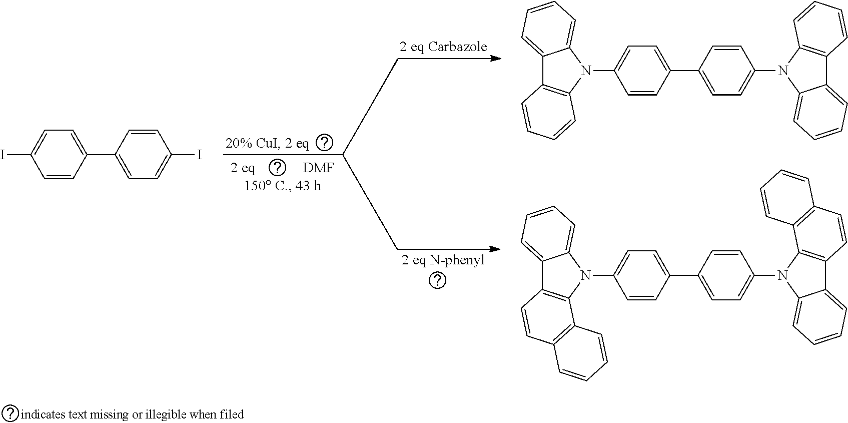 [SMILES: Ic1ccc(-c2ccc(I)cc2)cc1 ; c1ccc2c(c1)ccc1c3ccccc3n(-c3ccc(-c4ccc(-n5c6ccccc6c6ccc7ccccc7c65)cc4)cc3)c21 ; c1ccc2c(c1)c1ccccc1n2-c1ccc(-c2ccc(-n3c4ccccc4c4ccccc43)cc2)cc1]

A preferred cross-coupling reaction is the “Suzuki”. It has the following advantages:
1. the reaction occurs at mild reaction conditions (i.e low temperature, atmospheric pressure);
2. the reaction may use widely available common boronic acids;
3. inorganic by-products are easily removed from reaction mixture;
4. the reaction is stereoselective;
5. the reaction is less toxic than other competitive methods;
6. the reaction will take place in the presence of other functional groups, i.e group protecting is not always necessary; and
7. the reaction makes use of relatively cheap reagents, the reaction is easy to prepare, and the reaction is “green.”

Many palladium catalysts and precursors have been developed for the Suzuki reaction and are commercially available from vendors like Aldrich. Specific catalysts examples include:

air stable catalysts such as: palladium(II) acetylacetonate

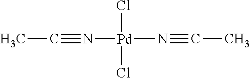

bis(acetonitrile)dichloropalladium(II),

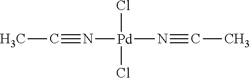

Palladium(II) trifluoroacetate

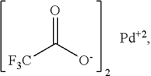

tris(dibenzylideneacetone)dipalladium(0)

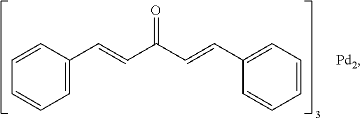

trichlorobis(tricyclohexylphosphine)palladium(II)

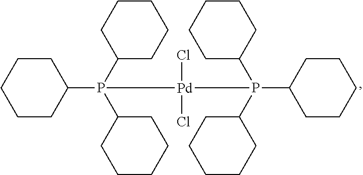

Bis(di-tert-butyl(4-dimethylaminophenyl)phosphine)dichloropalladium(II)

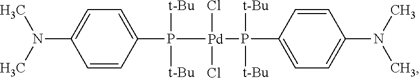

[1,1′-Bis(diphenylphosphino)ferrocene]dichloropalladium(II), complex with dichloromethane

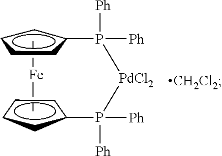

and air or moisture sensitive catalysts: Bis(triphenylphosphine)palladium(II) dichloride

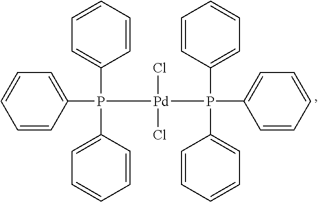

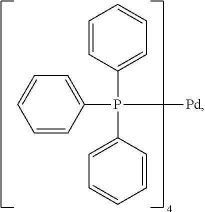

### Tetrakis(triphenylphosphine)palladium(0)

### Bis(dibenzylideneacetone)palladium(0)

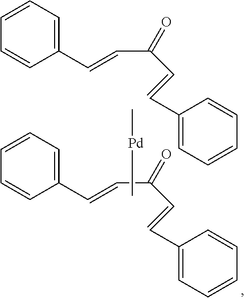

Dichlorobis(tri-o-tolylphosphine)palladium(II)

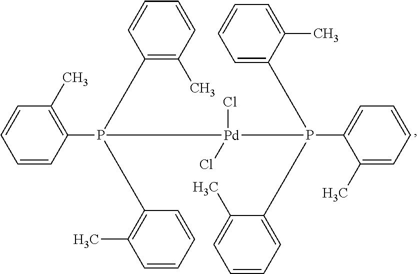

The molecular glass mixture made by the Suzuki reaction comprises at least two nonpolymeric, thermoplastic compounds, each thermoplastic compound independently conforming to the structure:

′(R)—Y—(Z)

wherein Y represents a triple bond, a double bond, or a single bond link. each R and Z represents independently a monovalent aliphatic or cycloaliphatic hydrocarbon group having 1 to 20 carbon atoms, an aromatic group or a multicyclic aromatic nucleus.

Examples of acceptable monovalent halides include:

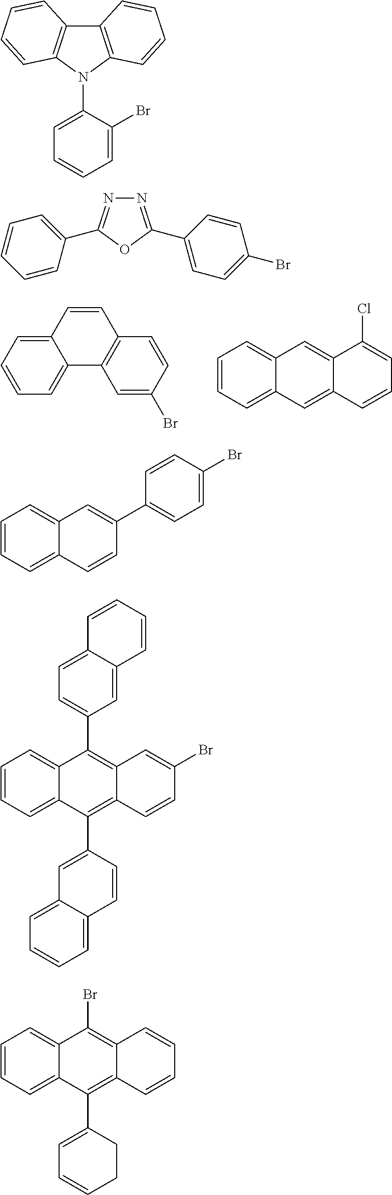

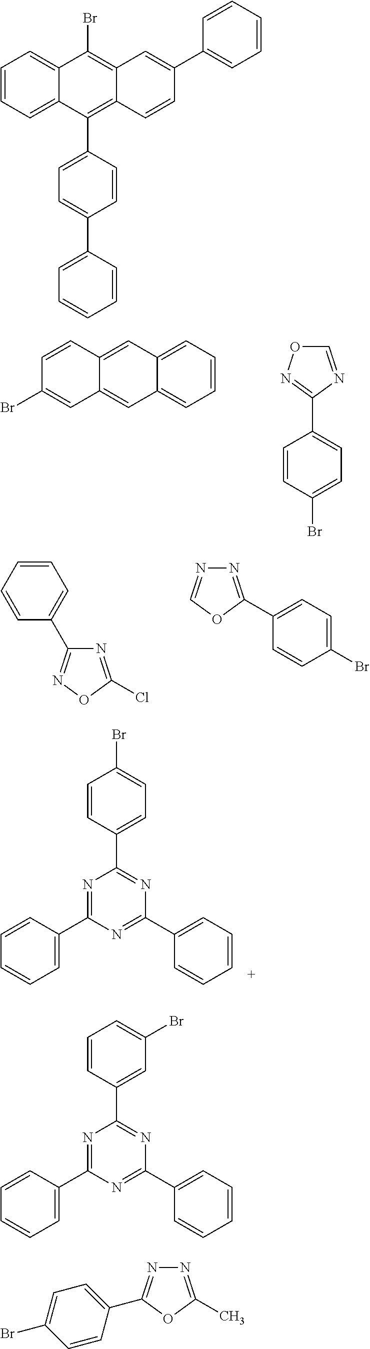

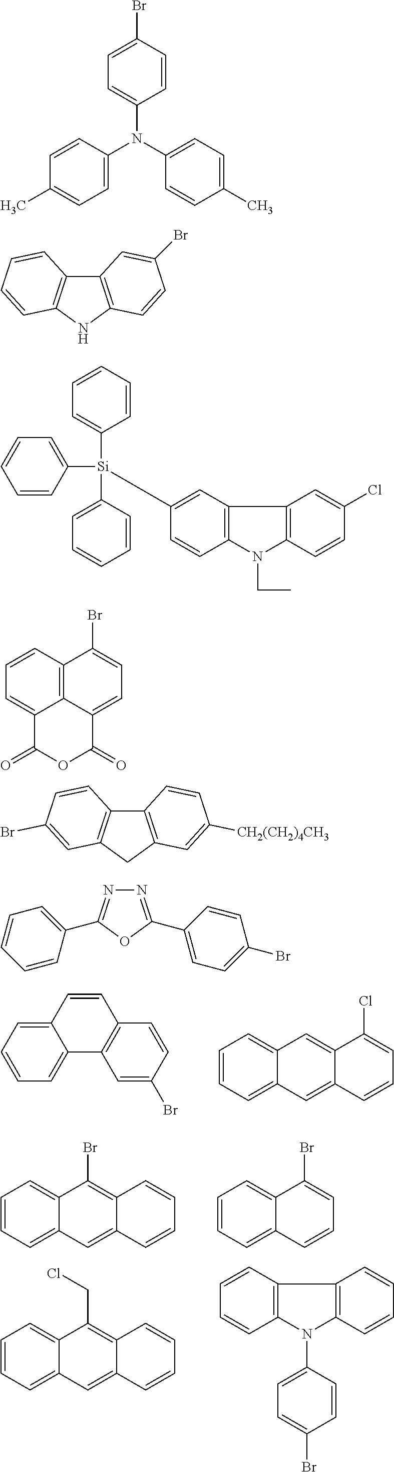

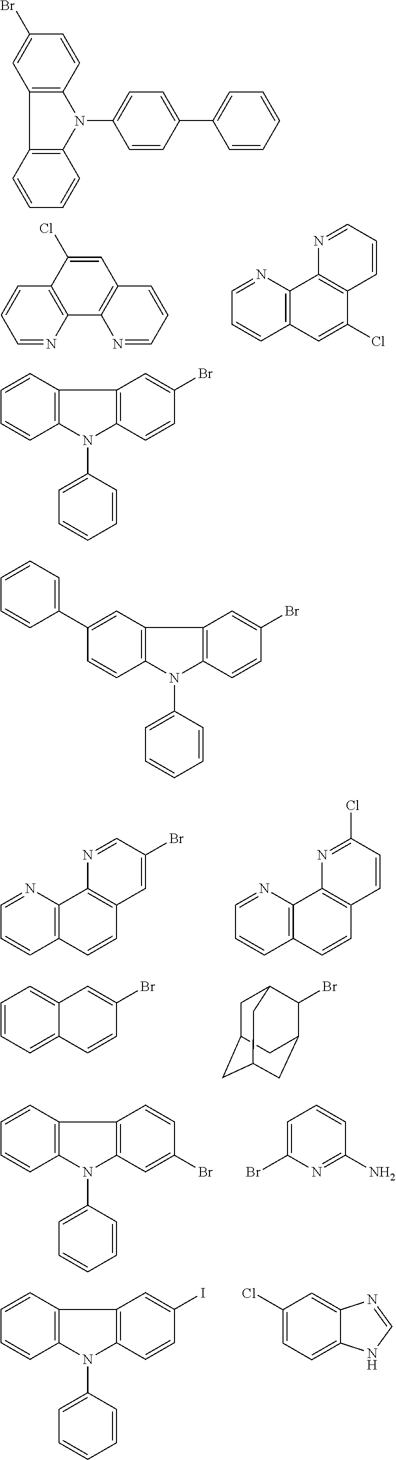

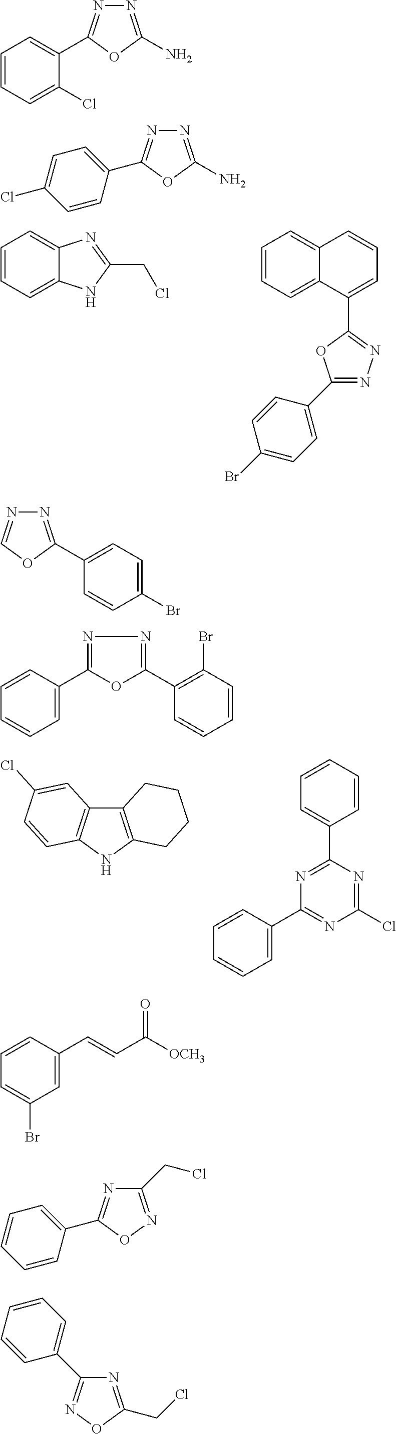

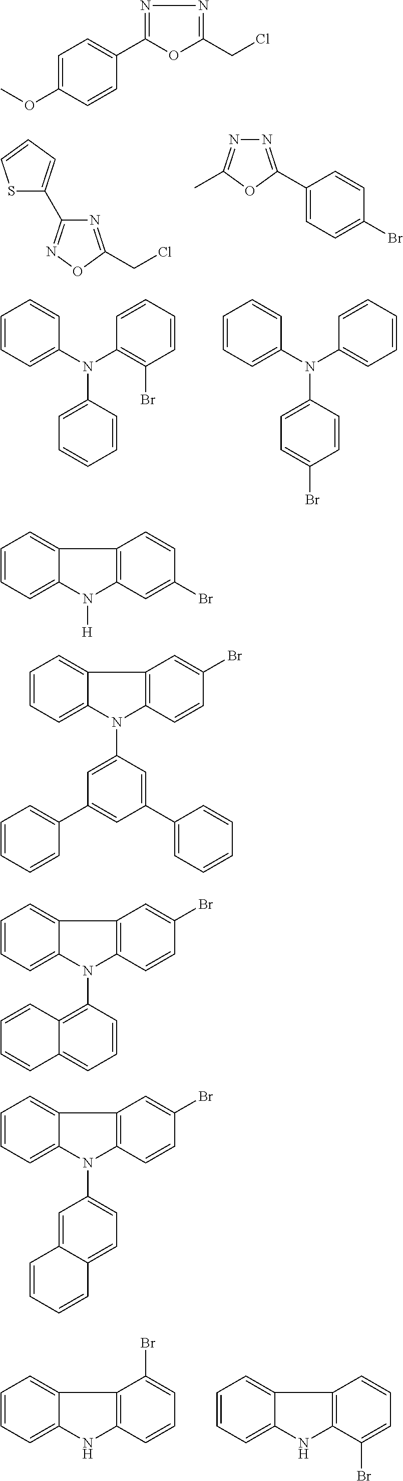

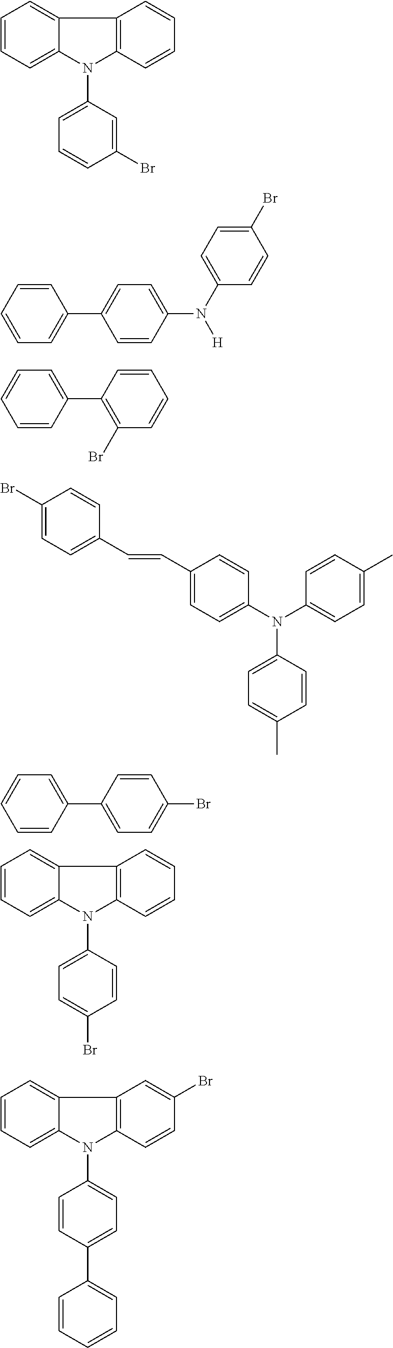

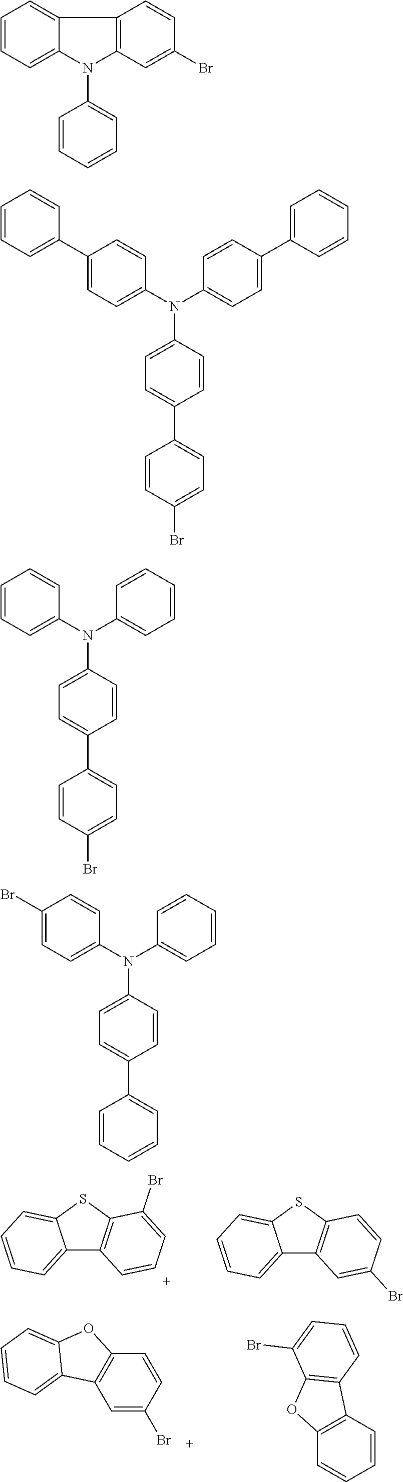

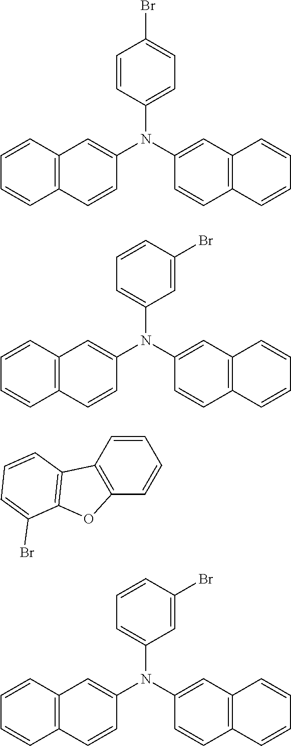

Example for specific monovalent boronic acids include:

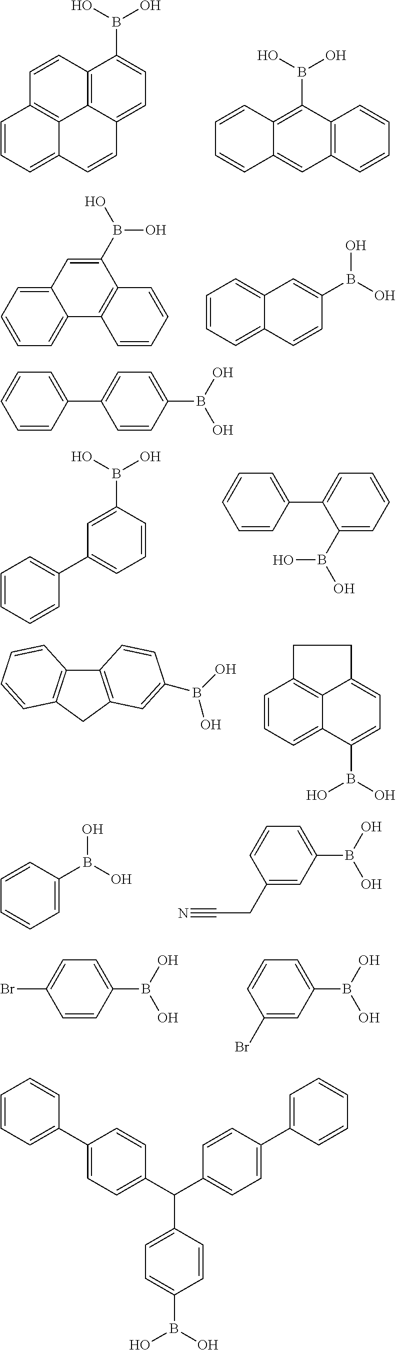

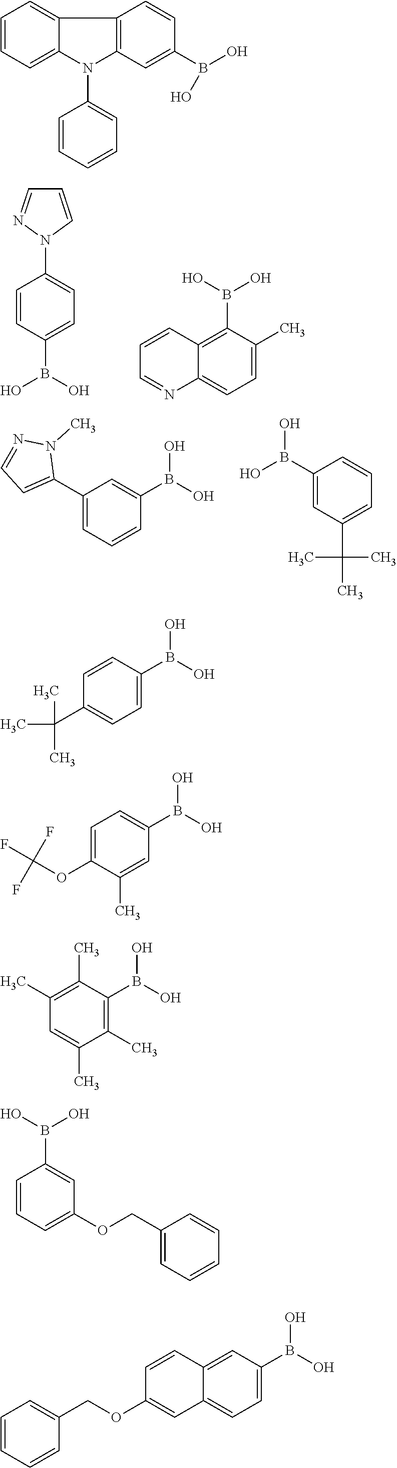

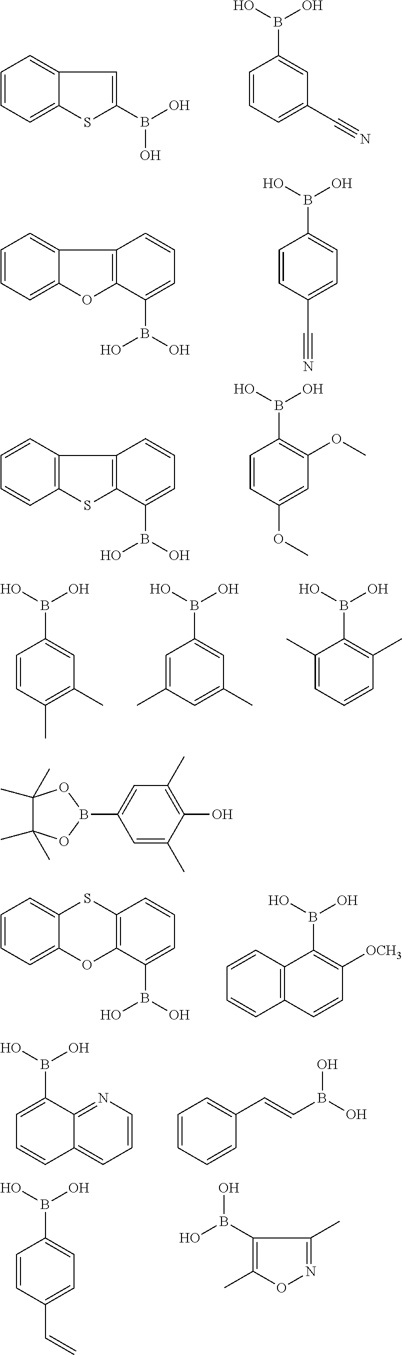

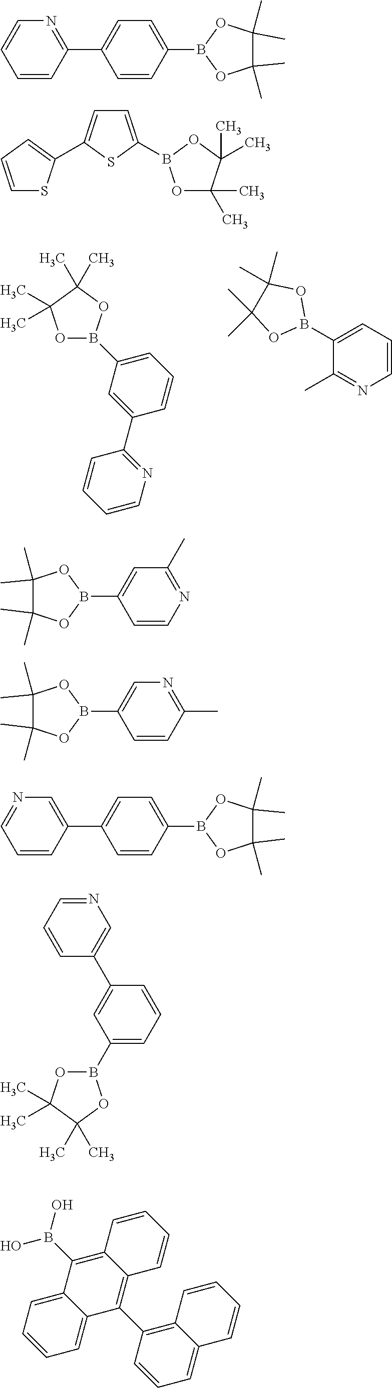

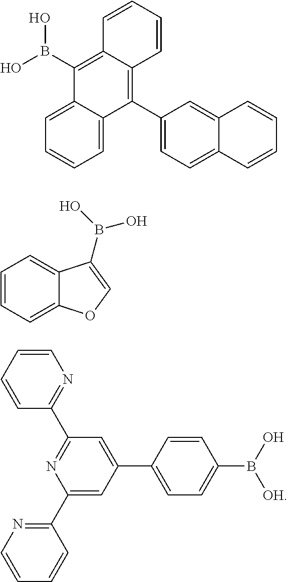

Another preferred coupling reaction is the Heck reaction. The advantages of the Heck reaction include:
1. the reaction can be assisted by microwave energy;
2. the reaction is phosphine-free using phosphine-free Pd(OAc)2-Guanidine catalyst;
3. the reaction is compatible with a wide range of chemical functionalities;
4. regioselectivity can be controlled by the reaction conditions, by the substituents on the arylene component, by living groups and by the choice of olefinic component; and
5. the reaction has very few side reactions.

Many of the catalysts used for the Suzuki reaction are used for the Heck reaction, including those listed in the description of the Suzuki reaction provided above.

Specific examples of monovalent olefins include:

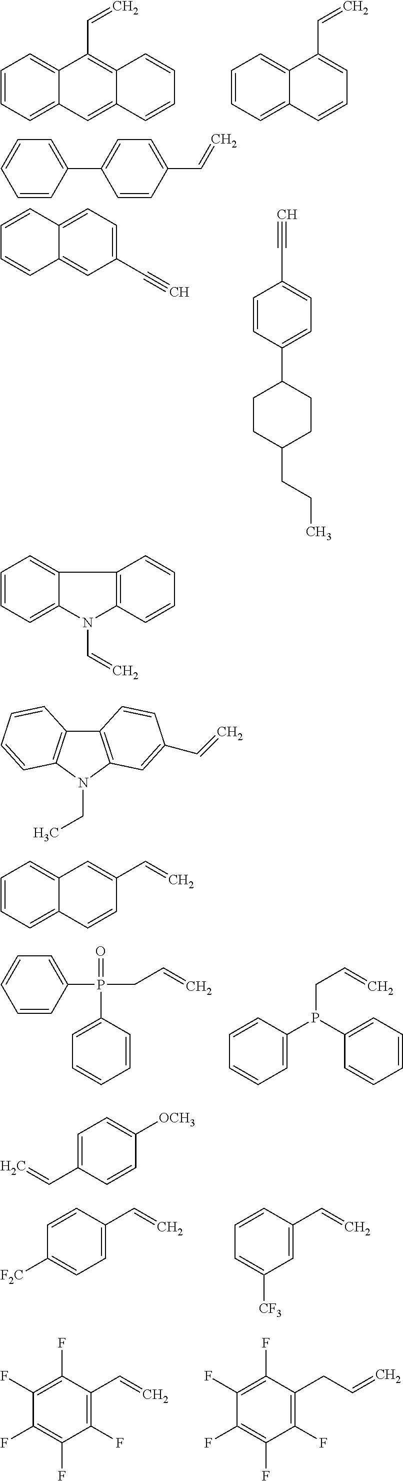

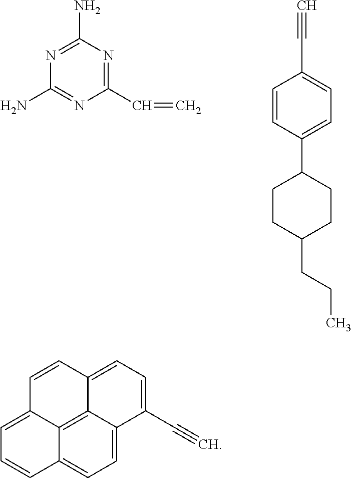

In one variation of the invention, mono-halides are prepared via the N-arylation of carbazoles and iminoaryls by aryl halides. Examples of H-carbazoles and iminodiarylenes include:

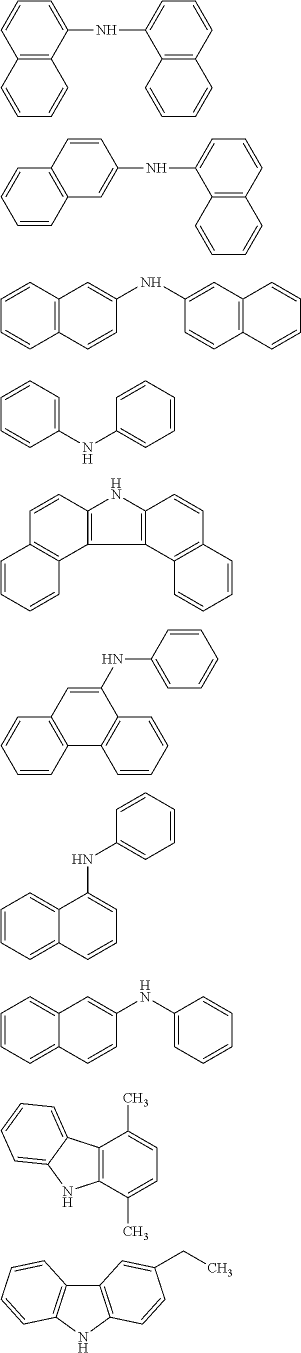

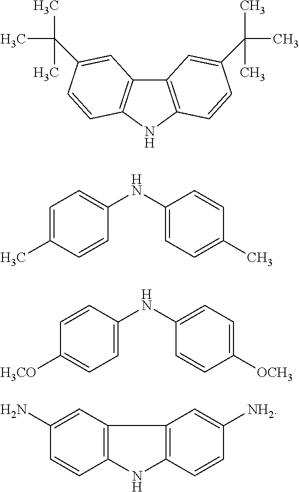

Examples of aryl halides include:

In the fifth embodiment of the invention each R and Z independently has the same molecular weight, resulting in all the components of the mixture being isomeric, that is they have the same molecular weight; thus approximately the same vapor pressure. This ensures thermal deposition of the mixture without fractionation. This is accomplished by using monovalent starting materials that are isomeric. Specific examples of isomeric monovalent starting materials for the coupling reactions of this invention include:

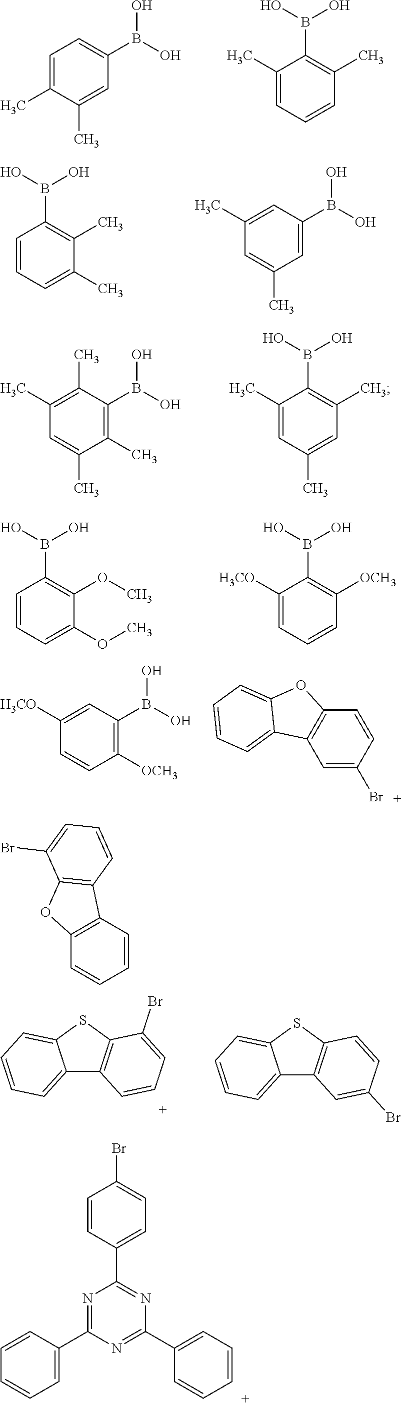

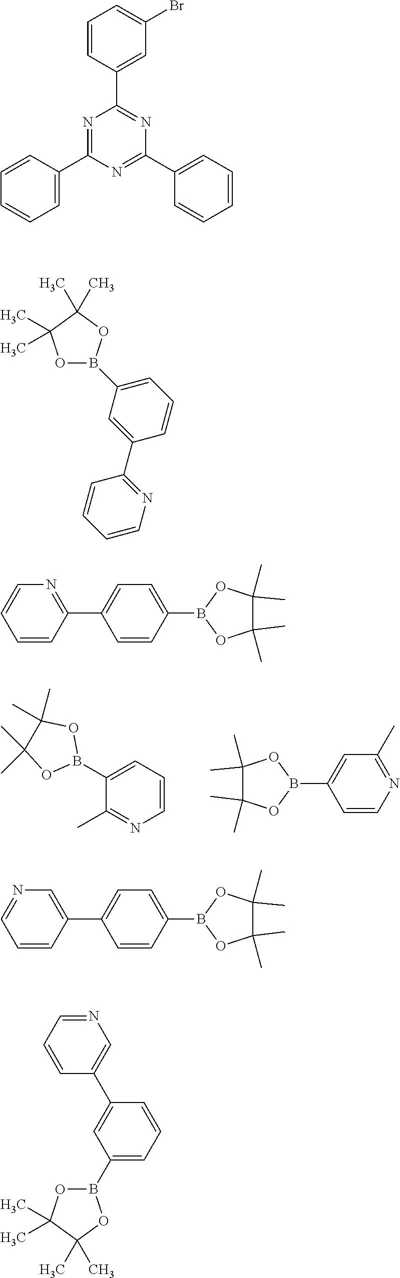

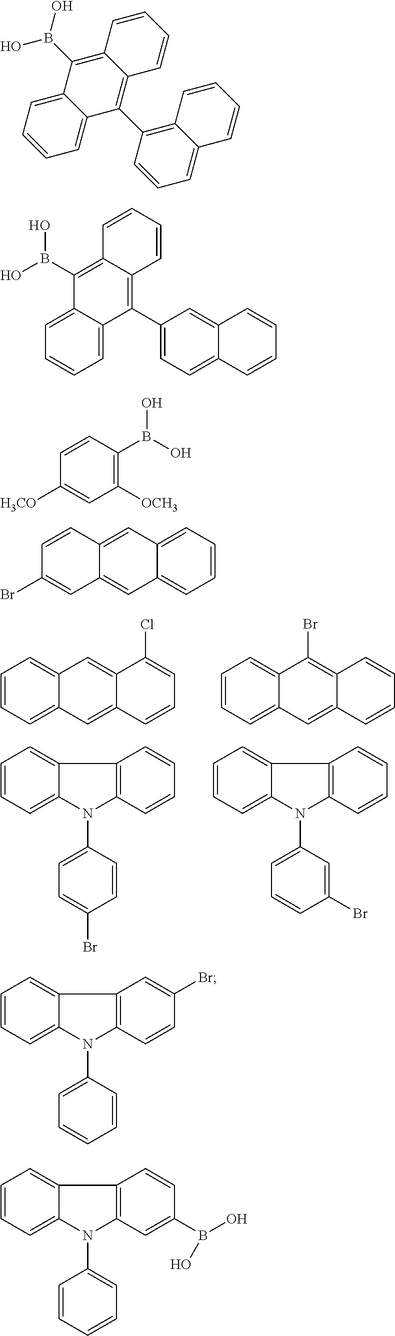

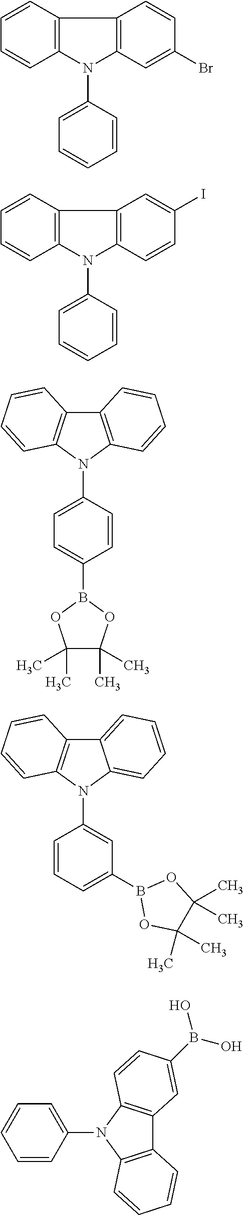

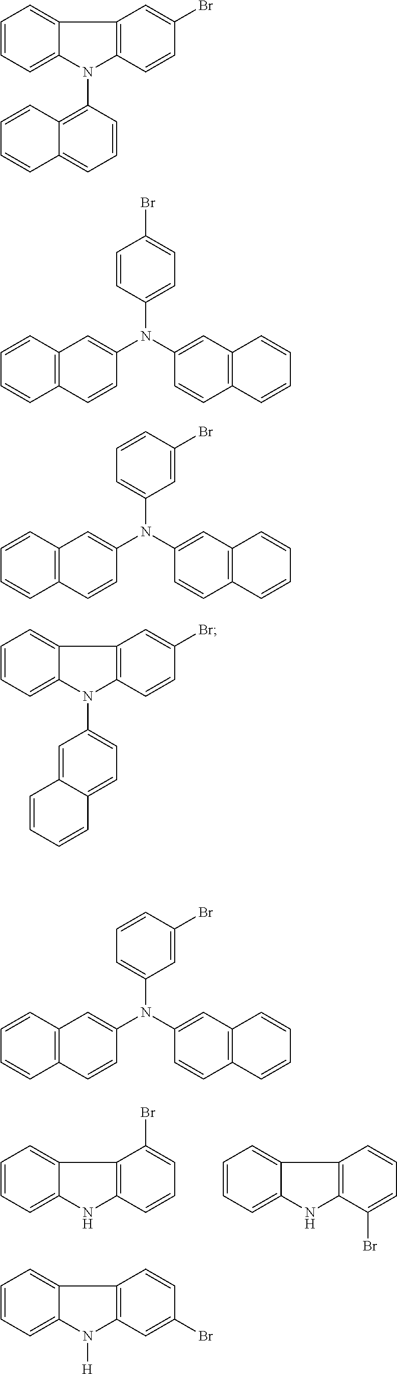

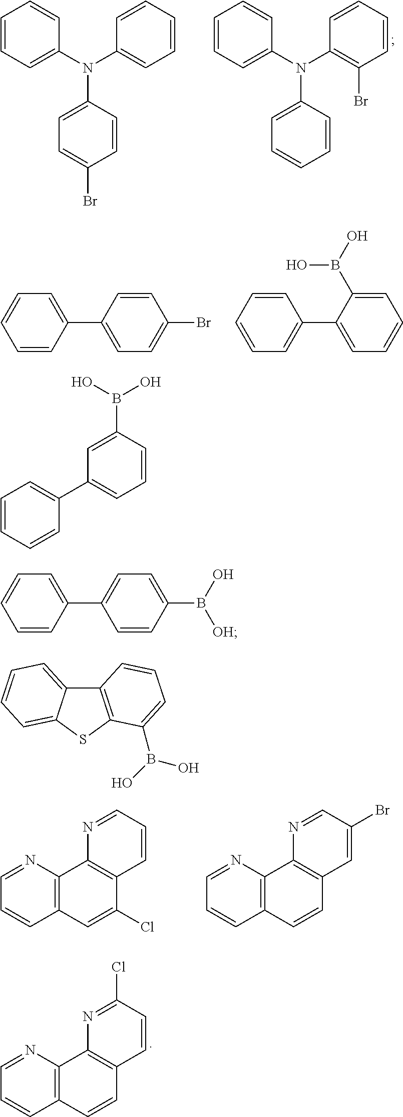

### General Procedure

An important object of this invention is to provide a method of providing truly non-crystallizable charge transporting molecular glass mixtures; truly non-crystallizable luminescent molecular glass mixtures; and combinations thereof that can be easily purified by simple and economic processes. Truly amorphous materials by definition cannot be recrystallized. Thus because of that it is very difficult, or perhaps potentially costly to purify charge transport molecular glass mixtures containing high level of impurities and other compositions.
Accordingly, this invention only uses reactions that are quantitative, that is the reaction is near 100 percent complete; with either no byproducts; or with byproducts that can be easily solubilized in water or other solvents and extracted efficiently.

Furthermore the procedure of this invention calls for pre-purification of all starting materials by either recrystallization, sublimation, or distillation or other purification methods to purity level required for poly-condensation reactions. This procedure eliminates the transport of unwanted impurities from any of the starting materials to the produced amorphous charge transport materials.

The following are specific examples of reaction procedures.

1. Coupling Reaction Via the Heck Reaction

One equivalent of a recrystallized multivalent halogenated aliphatic or cycloaliphatic hydrocarbon groups having 1 to 20 carbon atoms or an aromatic group is dissolved in dry dimethylformamide at 80° C. under a nitrogen atmosphere. Pd(OAc)₂ (0.05 equivalent), tri(o-tolyl)phosphine, “TOP” (0.30 equivalent) dissolved and stirred for 1 hour (h). Then two equivalent of the equimolar mixture consisting of three vinyl monovalent aliphatic or cycloaliphatic hydrocarbon group having 1 to 20 carbon atoms, an aromatic group or a multicyclic aromatic nucleus is added, dissolved and heated overnight to 100° C. with stirring. After 24 hours, the reaction mixture is cooled to room temperature and poured into a large amount of methanol. The resulting precipitate is stirred for 1 hour in methanol. The crude molecular glass mixture is filtered off and dissolved in hot chloroform. The solution is filtered through a glass filter to remove residual catalyst particles, and precipitated in methanol. The obtained molecular glass mixture is dried in a vacuum oven at 40° C. for 2 days.

If necessary the mixture is further purified by column chromatography using silica gel and appropriate solvent, or solvent mixture.

The isolated material is characterized, using differential scanning calorimetry (DSC) and thermogravimetric analyisi (TGA) for thermal properties, and liquid chromatography, nuclear magnetic resonance (NMR) or both liquid chromatography and NMR for composition. The number of molecules N in the mixture is the product of the number of vinyl reactants V multiplied by the number of halogenated reactants H:

N=V*H.

For V=2 and H=3, N=6,

the following is a listing of specific examples of molecular glass mixtures that can be prepared by the procedure above:

1. Asymmetric Molecular Glass 1

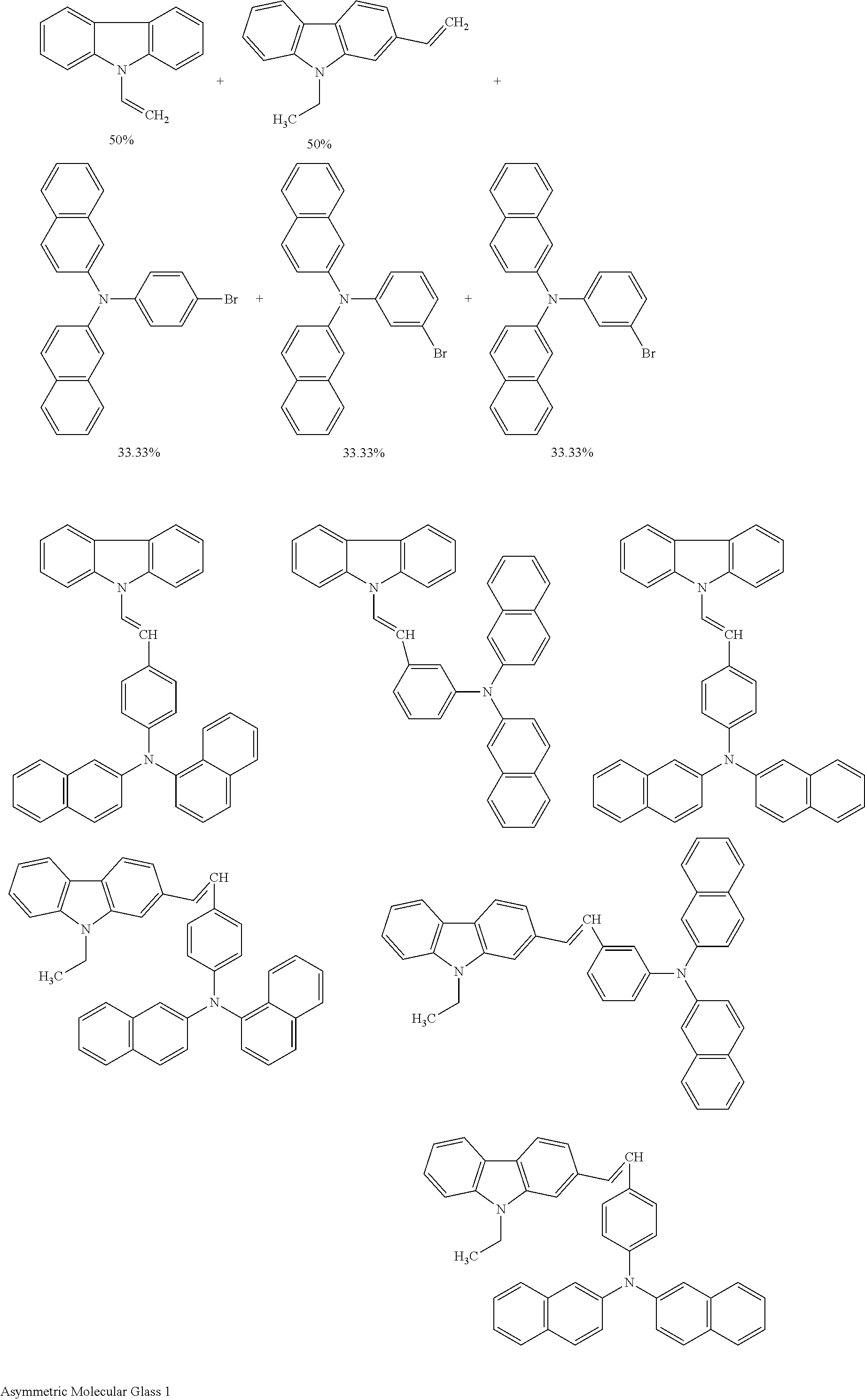

2. Asymmetric Molecular Glass 2

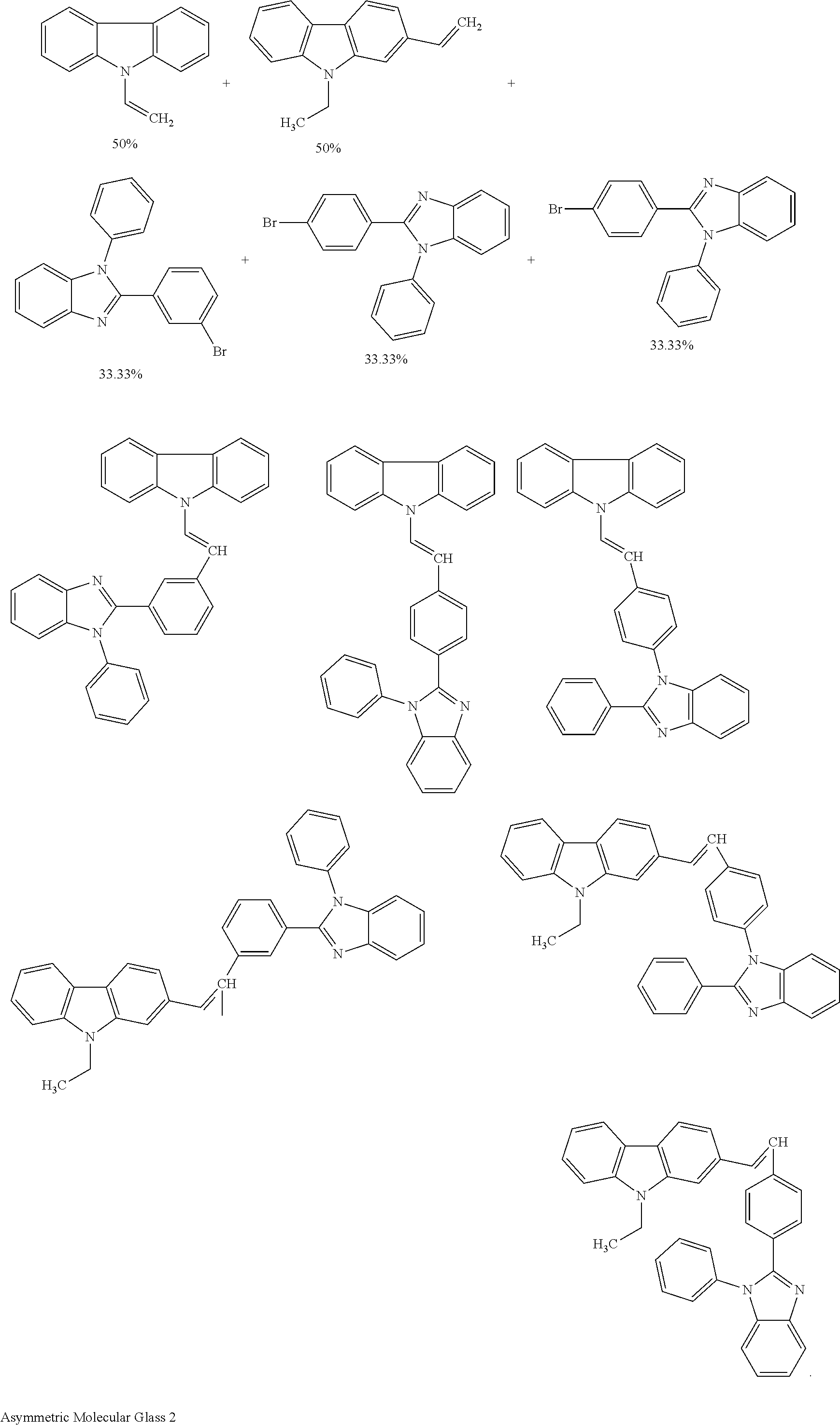

2. Coupling Reaction Via the Suzuki Reaction
One equivalent of a multivalent aliphatic or cycloaliphatic hydrocarbon group having 1 to 20 carbon atoms or an aromatic group and one equivalent of an equimolar mixture consisting of three or monovalent boronic acid or boronate aliphatic or cycloaliphatic hydrocarbon group having 1 to 20 carbon atoms, an aromatic group or a multicyclic aromatic nucleus are mixed together with 0.25 equivalent of Trioctylmethylammonium chloride in toluene. 2 moles (M) Na2CO2 aqueous solution is added to the suspension which is degassed with nitrogen for 30 minutes. Tetrakis(triphenylphosphine palladium(0), 0.0042 equivalent is added to the mixture. The reaction is then heated to reflux under nitrogen for one day. The reaction mixture is cooled down to room temperature and poured into a large amount of methanol water (9:1) mixture. The precipitate is purified by repeated dissolution in tetrahydrofuran (THF) and precipitation into methanol. The molecular glass mixture is obtained as a powder.

The isolated material is characterized, using differential scanning calorimetry (DSC) and thermogravimetric analyisi (TGA) for thermal properties, and liquid chromatography, nuclear magnetic resonance (NMR) or a combination of liquid chromatography and NMR for composition. The number of molecules N in the mixture is the product of the number of boronic reactants B multiplied by the number of halogenated reactants H:

N=B*H.

For B=3 and H=4, N=12

the following is a listing of specific examples of molecular glass mixtures that can be prepared by the procedure above:

3. Isomeric Asymmetric Glass Mixture 3

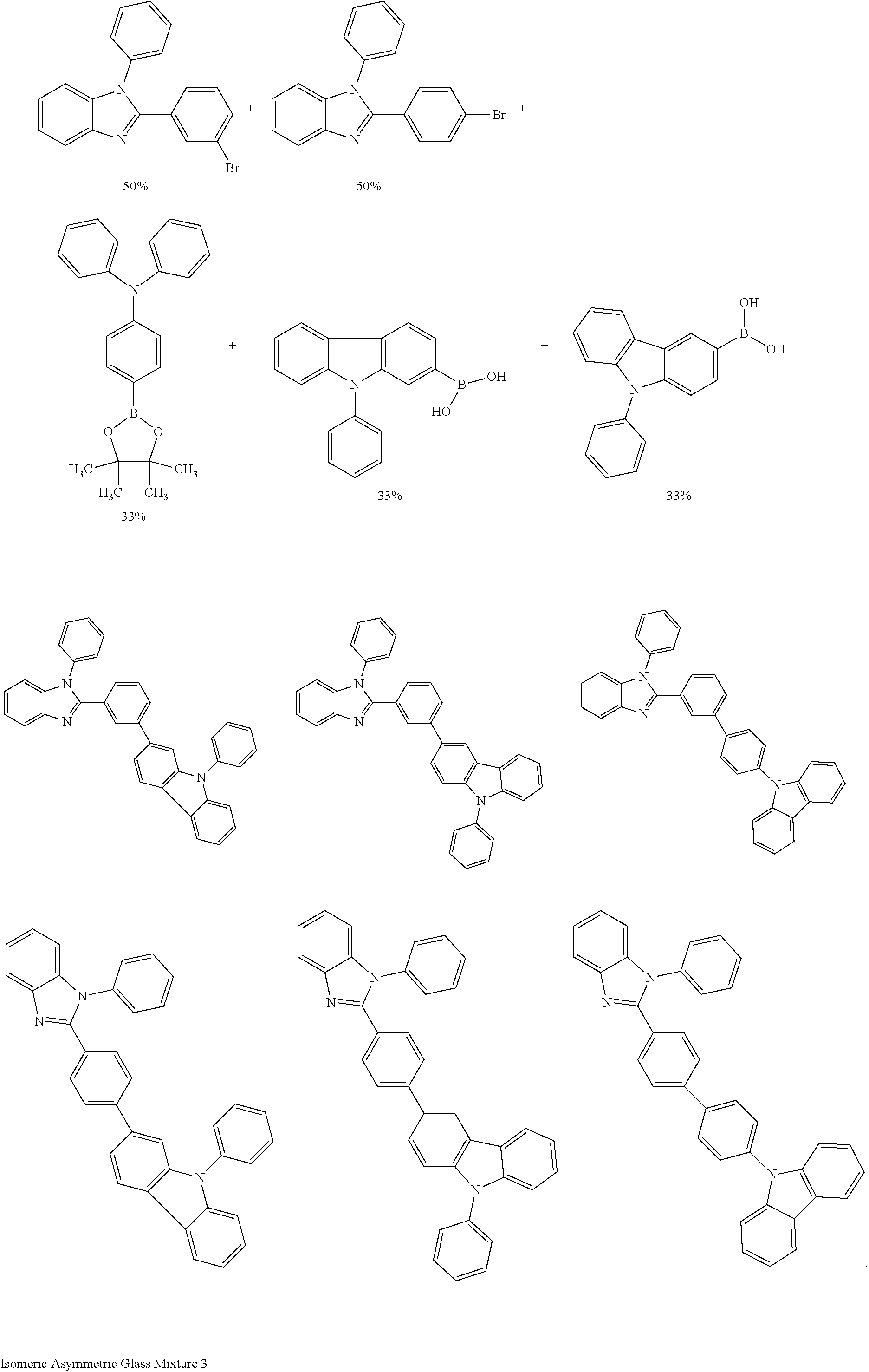

4. Isomeric Asymmetric Glass Mixture 4

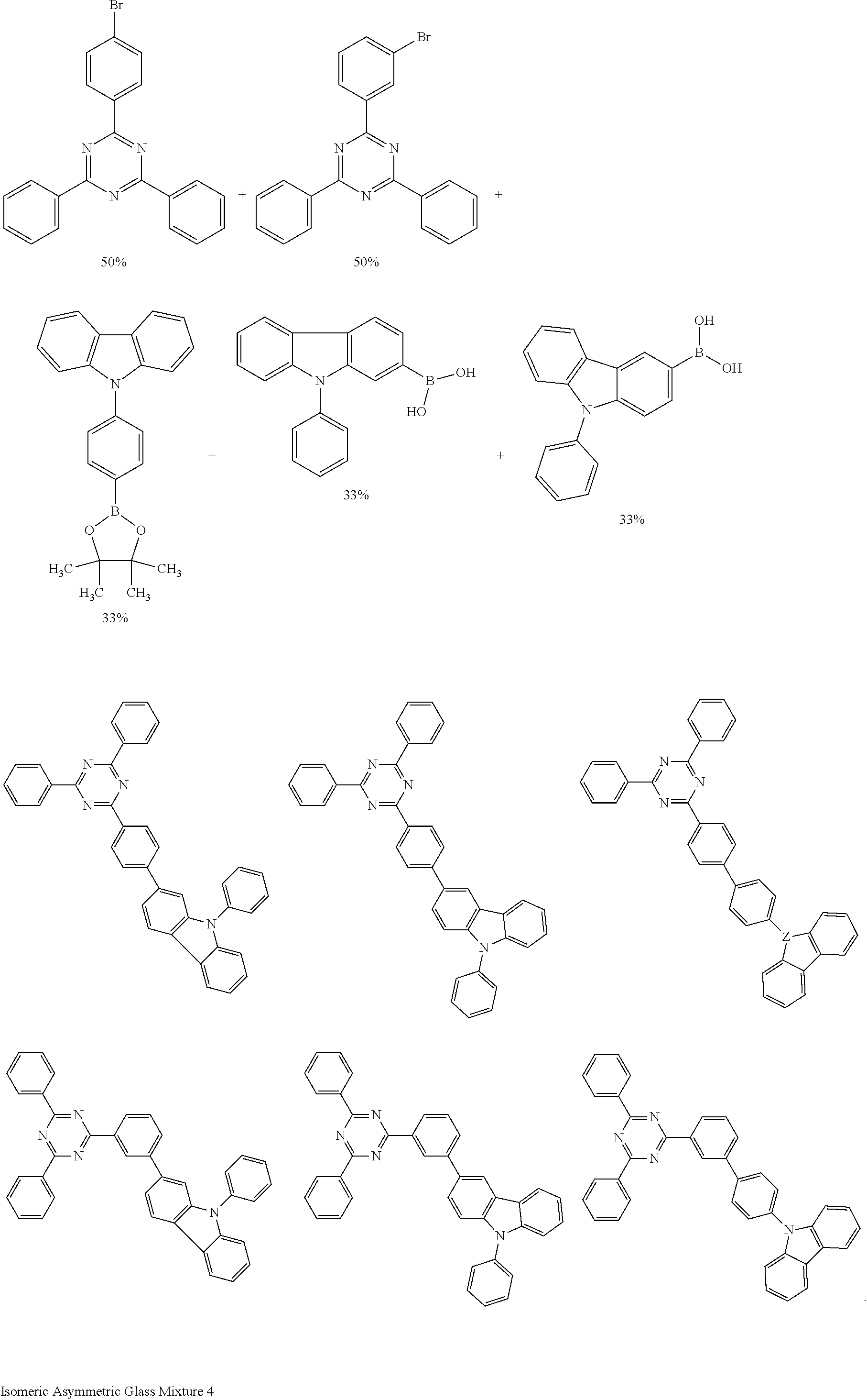

5. Isomeric Asymmetric Glass Mixture 5

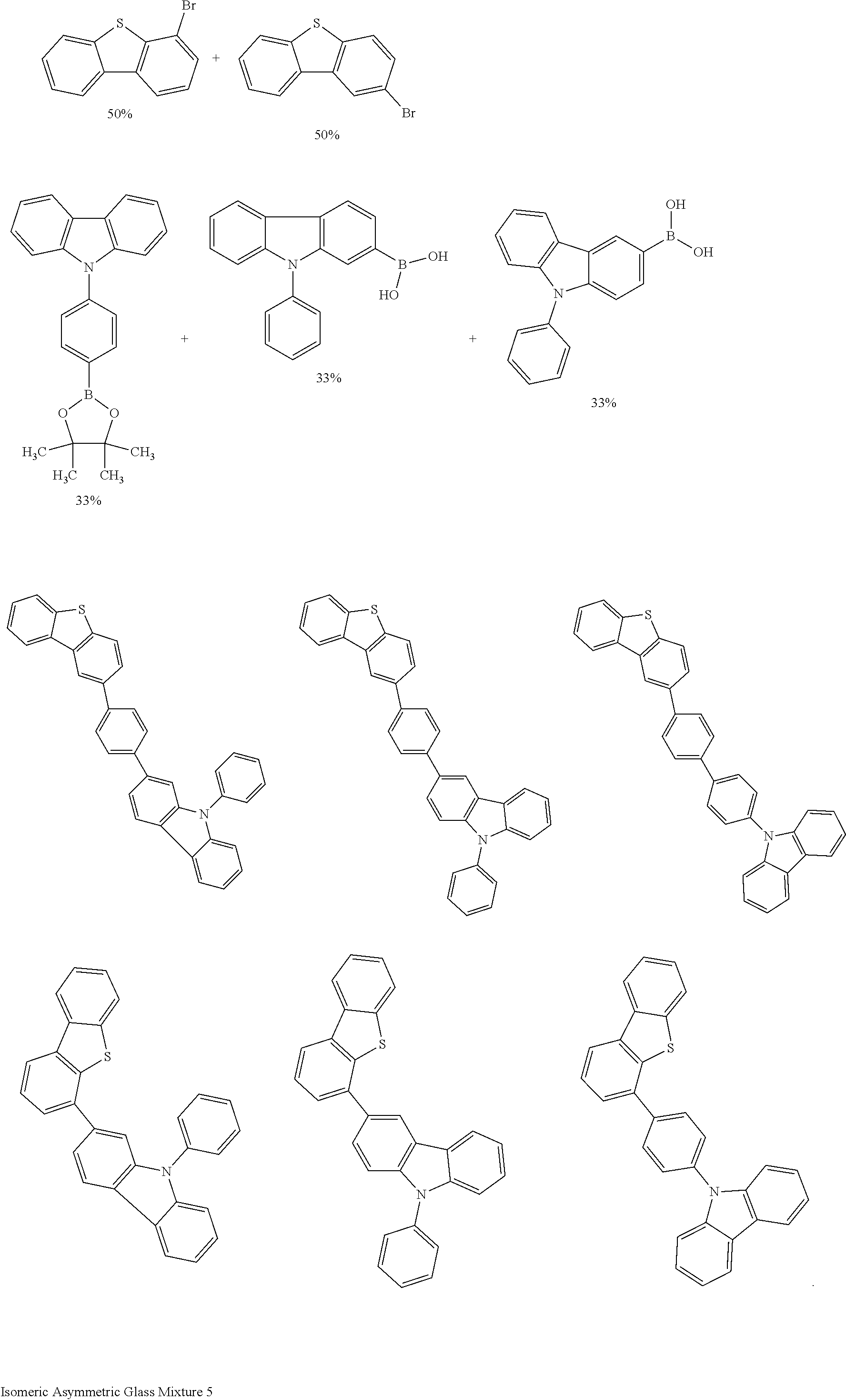

6. Isomeric Asymmetric Glass Mixture 6

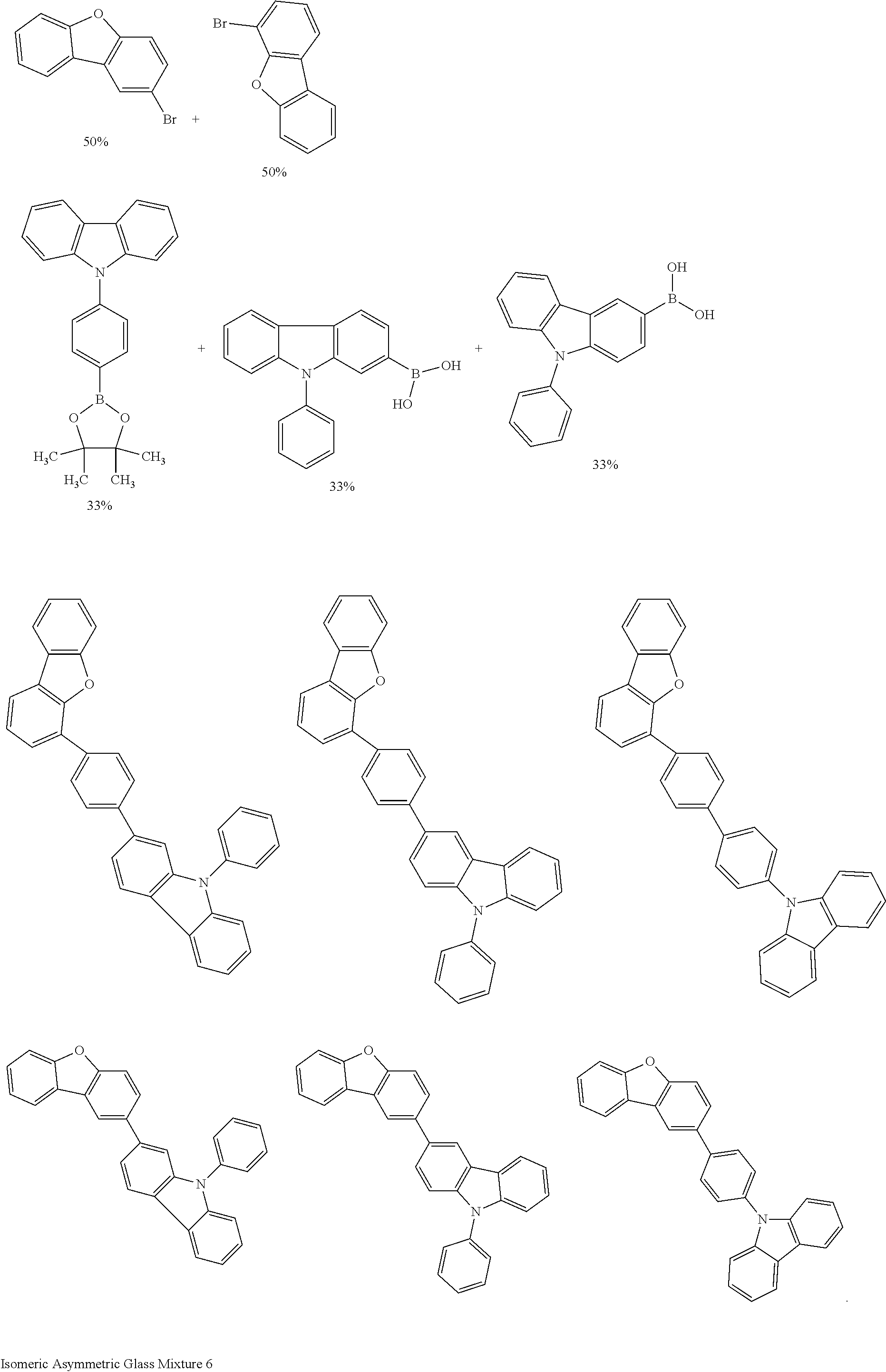

7. Isomeric Asymmetric Glass Mixture 7

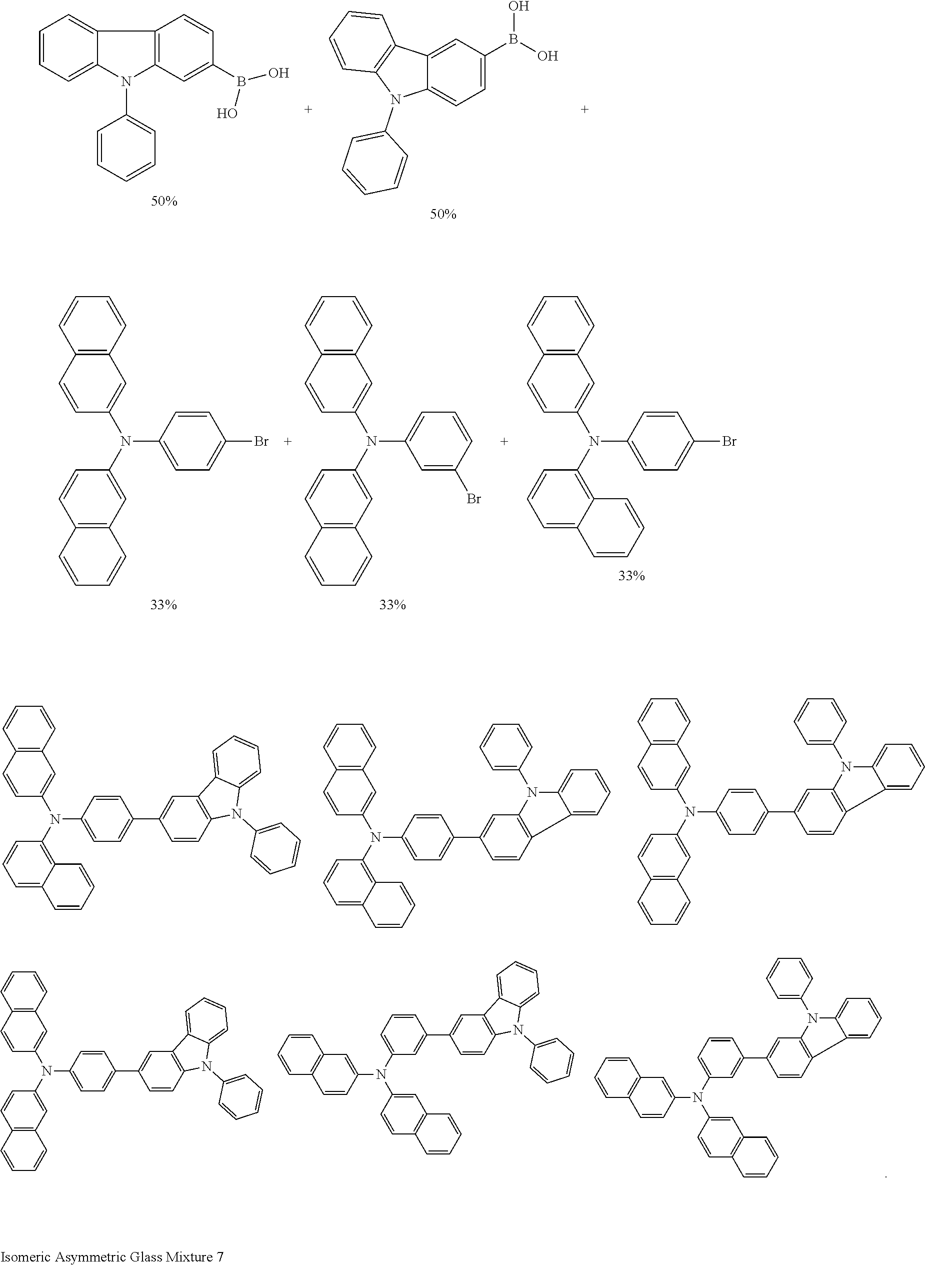

8. Isomeric Asymmetric Glass Mixture 8

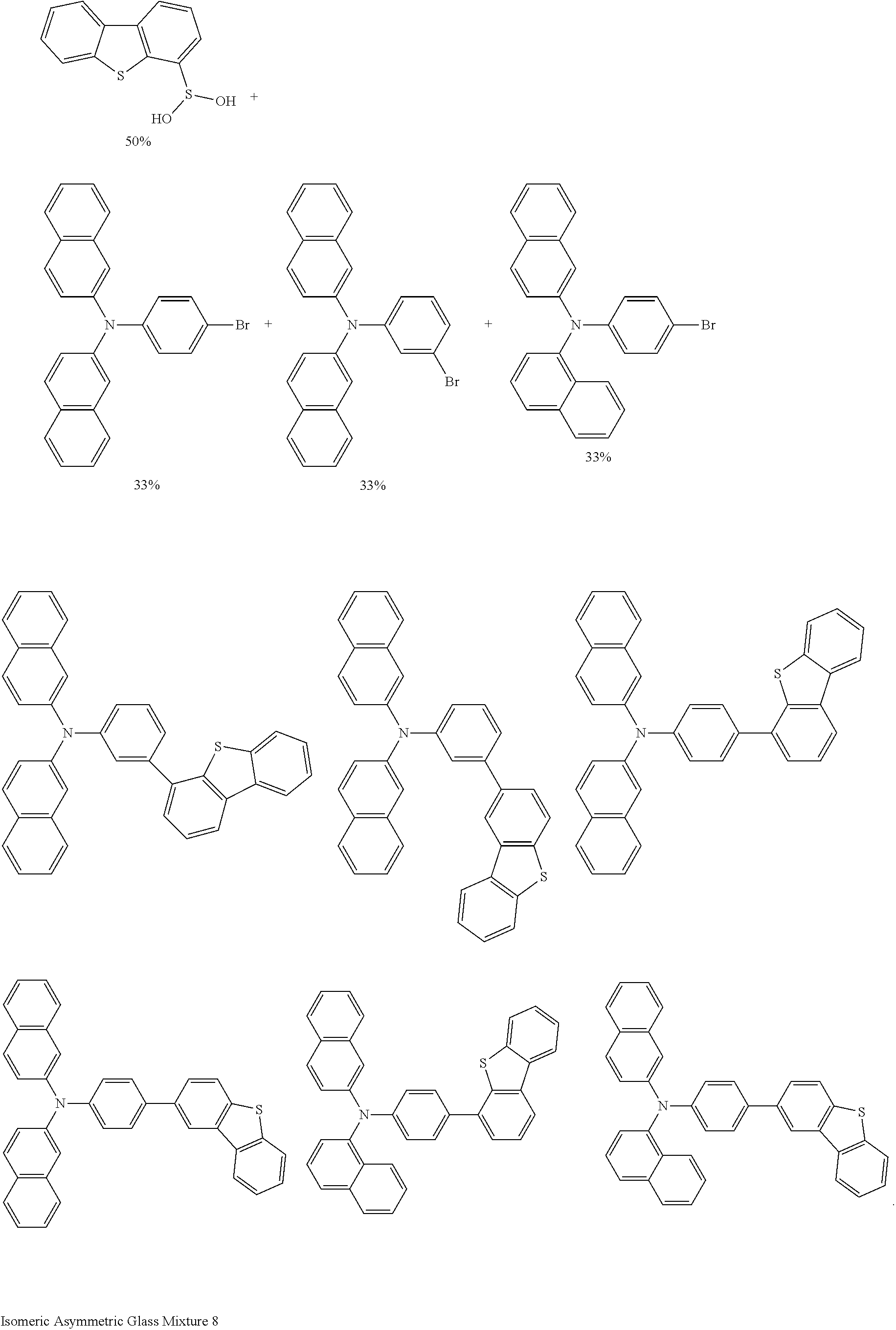

9. Isomeric Asymmetric Glass Mixture 9

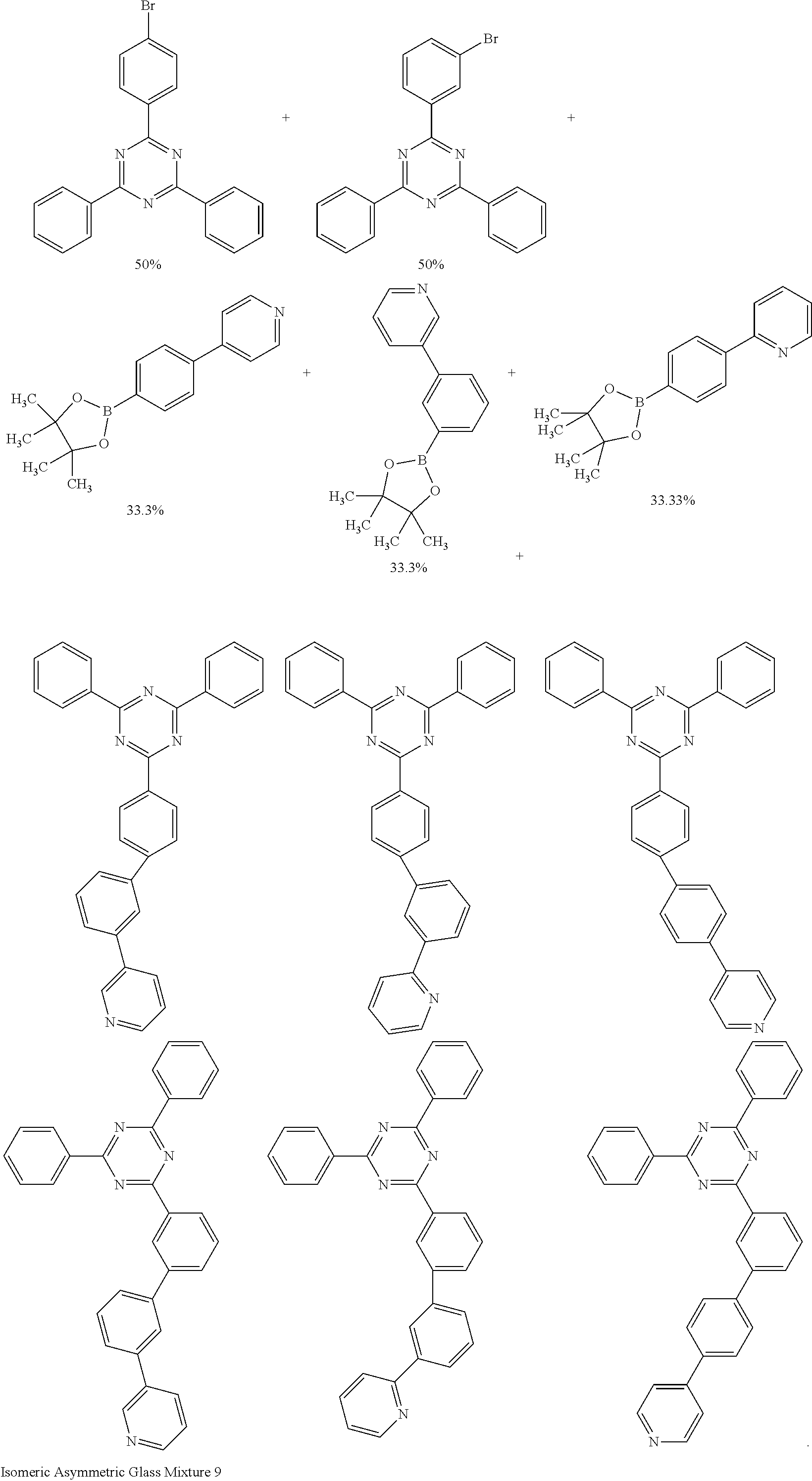

10. Isomeric Asymmetric Glass Mixture 10

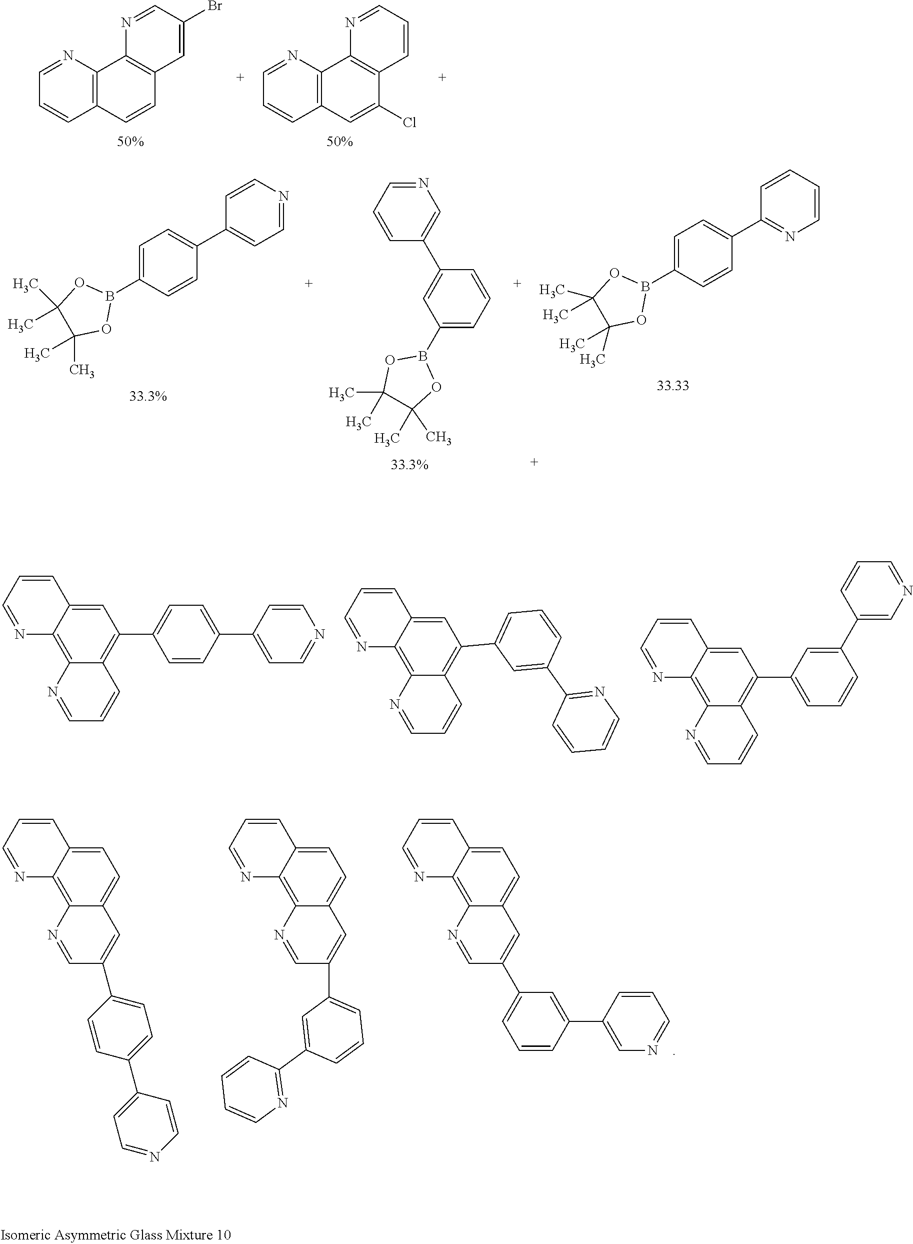

### EXAMPLES

### Example 1

The charge-transporting molecular glass mixtures, the luminescent molecular glass mixtures, and combinations thereof of the invention can be used in organic photoactive electronic devices, such as organic light emitting diodes (OLED) that make up OLED displays. The organic active layer is sandwiched between two electrical contact layers in an OLED display. In an OLED, the organic photoactive layer emits light through the light-transmitting electrical contact layer upon application of a voltage across the electrical contact layers.

It is well known by experts in the art, to use organic luminescent compounds as the active component in light-emitting diodes. Simple organic molecules, conjugated polymers, and organometallic complexes have been used. Devices that use photoactive materials frequently include one or more charge transport layers, which are positioned between a photoactive (e.g., light-emitting) layer and a contact layer (hole-injecting contact layer). A device can contain two or more contact layers. A hole transport layer can be positioned between the photoactive layer and the hole-injecting contact layer. The hole-injecting contact layer may also be called the anode. An electron transport layer can be positioned between the photoactive layer and the electron-injecting contact layer. The electron-injecting contact layer may also be called the cathode. Charge transport materials can also be used as hosts in combination with the photoactive materials.

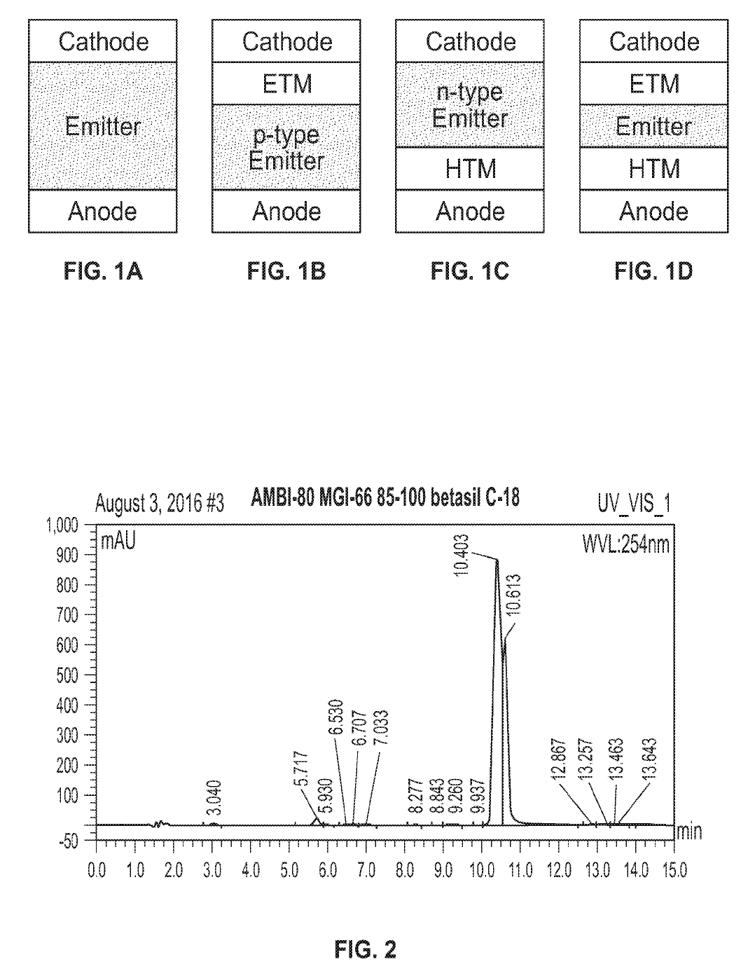

FIGS. 1A-1D show common OLED architectures, not in scale, with a hole-transport material (HTM) and an electron-transport material (ETM), (“Electron Transport Materials for Organic Light-Emitting Diodes’ A. Kulkarni et al, Chem. Mater. 2004, 16, 4556-4573).

The luminescent molecular glass mixtures of the invention can be used either as host, dopant or non-doped emitter layers in those structures, depending on the composition, the structure and properties of the luminescent moieties. The charge transport molecular glass mixtures of the invention can also be used in fluorescent as well phosphorescent emitter systems.

It is well understood that these materials have to be optimized for particular device configuration. The hole transport layer materials (HTL) need to have the highest occupied molecular orbital (HOMO) level aligned with the corresponding HOMO level of the host to assure the hole flow into the emissive layer zone with minimal barrier for injection, whereas the HTL lowest occupied molecular orbital (LUMO) has to be sufficiently high to prevent electron leakage from the host into the HTL. A similar set of rules, but with the opposite sign, exists for the interface of the host with the electron transport layer (ETL): The LUMO levels need to be aligned, and the ETL HOMO sufficiently deep to provide charge confinement. Triplet exciton energies of the materials in both charge transport layers should be significantly higher than the highest triplet level of all the emitters to prevent emissive exciton quenching. The triplet energy constraints also apply to the host materials, but with the requirements less stringent compared to those of hole and electron transport molecules. In addition, the positions of the HOMO of the HTL and LUMO of the ETL will have to match the work functions of both electrodes to minimize charge injection barriers. (E. Polikarpov, A B. Padmaperuna, “Materials Design Concepts for Efficient Blue OLEDs: A Joint Theoretical and Experimental Study”, Material Matters, Vol 7, No 1, Aldrich Materials Science).

### Example 2

2.68 grams (6.9 millimole (mmol)) of 2-(4-Bromophenyl)-4,6-diphenyl-1,3,5-triazine, 2.68 grams (6.9 mmol) of 2-(3-Bromophenyl)-4,6-diphenyl-1,3,5-triazine, 1.87 grams (5.055 mmol) of 9H-Carbazole-9-(4-phenyl) boronic acid pinacol ester, 1.87 grams (5.055 mmol) of 3-(9H-Carbazol-9-yl)phenylboronic Acid, 1.87 grams (5.055) mmol of 9-Phenyl-9H-carbazol-3-ylboronic-acid, and 0.65 gram of XPhos Pd G2 (3 mole %) were added to a Schlenk flask, which was then purged under nitrogen, 41.4 mL dry THF, and 82.8 mL degassed 0.5M K3PO4 were sequentially added to the reaction flask under nitrogen. The flask was sealed, heated to 40° C. and stirred overnight. Three extracts of 30 milliliters diethyl ether are collected. The solution is evaporated with the rotovap and the resulting solid is re-dissolved in dichloromethane and let sit overnight. Black particulates precipitated from the solution. The mixture is filtered twice through silica gel and a yellow solution is obtained. The solvent is stripped off. The completely dried solid is re-dissolved in a small amount of tetrahydrofuran (THF) and precipitated into methanol and filtered to obtain a pale yellow material.

### High Pressure Liquid Chromatography Analysis

The sample was dissolved in tetrahydrofuran and analyzed by LC/MS on an AB Sciex QTrap mass spectrometer using atmospheric pressure chemical ionization (APCI) in positive ionization mode. The sample was chromatographed using reversed-phase gradient conditions. The primary “A” solvent was 0.01M ammonium acetate+0.01M acetic acid, pH 4.7 in HPLC-grade water. The secondary “B” solvent was a 1:1 v:v mixture of acetonitrile:2-propanol. The analyses were generated using gradient conditions (15/85-0/100 “A”/“B” in 10 minutes) at a flow rate of 0.25 mL/min. The reversed-phase HPLC column used was a Thermo Betasil C-18 [2.1 mm×150 mm]; 5 um particle size. UV detection was performed using a diode array detector scanning from 210 nm to 900 nm.

The crude sample was also analyzed by atmospheric pressure solids analysis (ASAP) mass spectrometry using an AB Sciex QTrap mass spectrometer. The sample was thermally desorbed from a glass capillary and subsequently ionized at atmospheric pressure in a nitrogen rich atmosphere. The capillary was inserted directly into the mass spectrometer source while the temperature was ramped from 150-550 C in 50 degree steps. The temperature at each step was held for 1 minute. Positive ion full scan data was acquired from 50-1700 amu.

The HPLC chromatogram at 254 nm for Example 2 is shown in FIG. 2. The HPLC assay is shown in table 2. Sample components responded weakly in positive ion APCI but favorably in positive ion ASAP. The positive ion mass to charge ratios (m/z) of the components that responded to the mass spectrometer are shown in table 2 demonstrating a major doublet (m/z=551) at elution time 10.40 and 10.61 minute with relative area of 66.30% and 31.25% respectively for a crude isomeric noncrystallizable molecular glass mixture of 97.36% purity.

### Sublimation

The crude sample was subjected to sublimation in a 1 mm glass tube using a Linberg/Blue furnace @ 270° C. at 100 millitor.

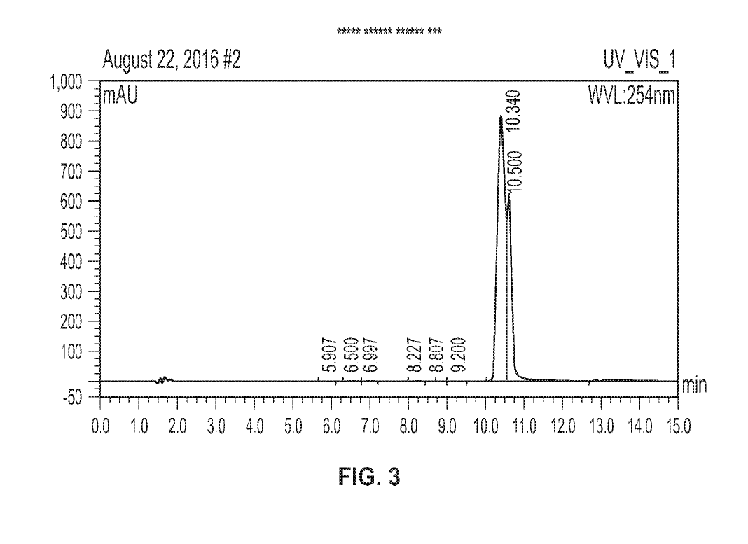

The sublimed sample was reanalyzed by HPLC at 254 nm and ASAP. The results are shown below in Table 3 and in FIG. 3.

After sublimation the HPLC shows a doublet (m/z=551) at 10.34 and 10.55 minute elution time with relative area of 67.25% and 32.48% respectively for an isomeric noncrystallizable molecular glass mixture of 99.73% purity.

### Thermal Characterization

Differential scanning calorimetry was used for thermal characterization for the mixture, using the following conditions:
temperature range: 0 to 200° C.
heating rate: 10° C./min
purge gas: nitrogen
flow rate: 50 cc/min

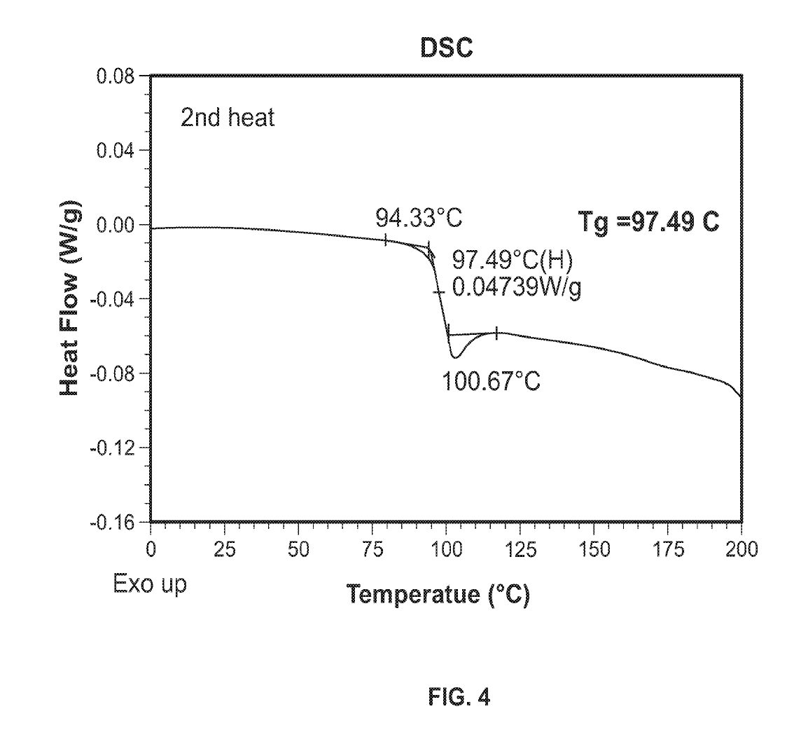

After three cycles above Tg, no crystallization was seen, The second cycle is shown in FIG. 4 presenting a glass transition temperature of 97.5° C.

### Device Fabrication

Using Example 2 as the host for a yellow phosphorescent emitter, three devices were fabricated on glass substrates pre-coated with 145 nm of ITO. The substrates are cleaned in standard Ultra T cleaner tool and baked at 120° C. for 2 hours. Next, the substrates were transferred into a vacuum chamber for sequential deposition of organic layers by thermal evaporation under a vacuum 10⁻⁶-10⁻⁷ Torr. During deposition, layer thicknesses and doping concentrations were controlled using calibrated deposition sensors. Next, a bilayer of 0.5 nm LiF|125 nm Al was deposited to form a cathode. Devices are encapsulated using standard metal can with UV adhesive and desiccant. The device emission area is 0.1 cm². No light extraction enhancement was used.

After OLED processing, the samples were fully characterized using the standard test procedures. This includes powering the devices using a Keithly 2400 power supply and measuring the electrical-optical characteristics using a PR-650 spectrophotometer. External quantum efficiencies (EQE) are calculated assuming that device emission is lambertian.

The results are shown in the table below

The materials of this invention provide a facile method to satisfy the set of energy alignment requirements in a given material by combining different molecular moieties that carry the desired electronic properties in one molecular glass mixture. The luminescent molecular glass mixtures of this invention provide many design freedoms to simplify the design of these devices. The true non-crystalline nature of these mixtures, their large entropy of mixing values are expected to contribute significantly to device stability and performance.

These examples of materials and applications are not meant to be exhaustive. Although the invention has been described with reference to specific embodiments, it is not intended to be limited thereto, rather those having ordinary skill in the art will recognize that variations and modifications may be made within the scope of the claims.

What is claimed is:

1. A composition comprising
a molecular glass mixture of non-polymeric compounds exhibiting a single thermal transition free of phase separation wherein said molecular glass mixture is characterized as amorphous, solid at about 20° C., and comprises at least two different compounds each independently corresponding to the structure ′(R)—Y—(Z)
wherein Y represents a triple bond, a double bond, or a single bond link; each R and Z represents independently a monovalent aliphatic or cycloaliphatic hydrocarbon group having 1 to 20 carbon atoms, an aromatic group or a multicyclic aromatic nucleus.

2. The composition of claim 1 wherein each R and Z is independently a monovalent hole-transporting moiety, a luminescent moiety, or a combination thereof.

3. The composition of claim 1 wherein each R and Z is independently a monovalent electron-transporting moiety, a luminescent moiety, or a combination thereof.

4. The composition of claim 1 wherein either R or Z is independently a monovalent electron-transporting moiety, a luminescent moiety, or a combination thereof; the other a monovalent hole-transporting moiety, a luminescent moiety, or a combination thereof.

5. The composition of claim 1 wherein each R independently has the same molecular weight, and each Z independently has the same molecular weight; whereras the molecular weight of R is different or the same as the molecular weight of Z.

6. The composition of claim 1 wherein all the components of the mixture are isomeric.

7. The composition of claim 1 wherein all the components of the mixture are asymmetric.

8. The composition of claim 1 wherein at least one of R or Z is a luminescent moiety.

9. The composition of claim 1 wherein all the components of the mixture are asymmetric and isomeric.

10. The composition of claim 9 wherein the luminescent moiety is a fluorescent moiety.

11. The composition of claim 10 wherein the luminescent moiety is a phosphorescent moiety.

12. The composition of claim 9 wherein the luminescent moiety is a thermally assisted delayed fluorescence moiety.

13. The composition of claim 1 wherein the molecular glass mixture is solvent-coatable.

14. The composition of claim 1 wherein the molecular glass mixture is vacuum-coatable.

15. The composition of claim 1 wherein the molecular glass mixture is noncrystallizable.

16. The composition of claim 15 further consisting of mixing a non-equilibrium molecular glass, a crystallizable molecule, or a combination thereof with said noncrystallizable molecular glass mixture in a ratio that yields a new noncrystallizable glass mixture, wherein the non-equilibrium glass, the crystallizable molecule, or a combination thereof is charge transporting, luminescent, or a combination thereof.

17. The composition of claim 1 wherein the molecular glass mixture is soluble in a solvent taken from the group consisting of water, acetone, 1-butanol, ethanol, 2-propanol, ethyl acetate, methanol, isopropyl acetate, acetonitrile, tetrahydrofuran, 2-methyltetrahydrofuran, dimethyl sulfoxide, acetic acid, and xylene.

18. An organic electronic device comprising multiple layers wherein at least one of the layers contain a hole-transporting, an electron-transporting, a bipolar, a luminescent molecular glass mixture, or a combination thereof of claim 1.

19. The organic electronic device of claim 18 wherein the organic electronic device is an organic light emitting diode.

20. The organic electronic device of claim 18 wherein the organic electronic device is a photonic device.

21. The organic electronic device of claim 18 wherein the organic electronic device is a solar cell device.

22. The organic electronic device of claim 18 wherein the organic electronic device is a field-effect transistor.

23. The organic electronic device of claim 18 wherein the organic electronic device is flexible.

24. The organic electronic device of claim 18 wherein the organic electronic device is transparent.

25. A process of making a molecular glass mixture wherein all the starting materials are pre-purified by recrystallization, distillation, sublimation, or other purification methods.

26. A process of making a molecular glass mixture wherein all the starting materials are monofunctional.
